(19) United States
(12) Patent Application Publication
(10) Pub. No.: US 2006/0276047 A1
(43) Pub. Date: Dec. 7, 2006

(54) Macroporous silicon microcavity with tunable pore size

(75) Inventors: Huimin Ouyang, Rochester, NY (US); Philippe M. Fauchet, Pittsford, NY (US); Marc Christophersen, Alexandria, VA (US)

Correspondence Address: NIXON PEABODY LLP - PATENT GROUP, CLINTON SQUARE, P.O. BOX 31051, ROCHESTER, NY, 14603-1051, US

(73) Assignee: University of Rochester, Rochester, NY (US)

(21) Appl. No.: 11/374,729

(22) Filed: Mar. 14, 2006

Related U.S. Application Data
(60) Provisional application No. 60/661,674, filed on Mar. 14, 2005.

(51) Int. Cl. H01L 21/00

(52) U.S. Cl. 438/753; 438/781; 438/49; 257/414

(57) ABSTRACT

A biological sensor which includes: a macroporous semiconductor structure comprising a central layer interposed between upper and lower layers, each of the upper and lower layers including strata of alternating porosity; and one or more probes coupled to the porous semiconductor structure, the one or more probes binding to a target molecule, whereby a detectable change occurs in a refractive index of the biological sensor upon binding of the one or more probes to the target molecule. Methods of making the biological sensor and methods of using the same are disclosed, as is a detection device which includes such a biological sensor.

The present invention claims priority to U.S. Provisional Patent Application No. 60/661,674, filed Mar. 14, 2005, which is hereby incorporated by reference in its entirety.

The present invention was made, at least in part, with funding received from the U.S. Army Research Office, grant numbers 5-28888 and 5-27987. The U.S. government may have certain rights in this invention.

### FIELD OF THE INVENTION

This invention relates to macroporous microcavity structures, as well as methods of making such macroporous microcavity structures and their use.

### BACKGROUND OF THE INVENTION

Ever increasing attention is being paid to detection and analysis of low concentrations of analytes in various biologic and organic environments. Qualitative analysis of such analytes is generally limited to the higher concentration levels, whereas quantitative analysis usually requires labeling with a radioisotope or fluorescent reagent. Such procedures are time consuming and inconvenient. Thus, it would be extremely beneficial to have a quick and simple means of qualitatively and quantitatively detecting analytes at low concentration levels.

Solid-state sensors and particularly biosensors have received considerable attention lately due to their increasing utility in chemical, biological, and pharmaceutical research as well as disease diagnostics. In general, biosensors consist of two components: a highly specific recognition element and a transducing structure that converts the molecular recognition event into a quantifiable signal. Biosensors have been developed to detect a variety of biomolecular complexes including oligonucleotide pairs, antibody-antigen, hormone-receptor, enzyme-substrate and lectin-glycoprotein interactions. Signal transductions are generally accomplished with electrochemical, field-effect transistor, optical absorption, fluorescence or interferometric devices.

It is known that the intensity of the visible reflectivity changes of a porous silicon film can be utilized in a simple biological sensor, as disclosed in U.S. Pat. No. 6,248,539 to Ghadiri et al. As disclosed therein, the detection and measurement of the wavelength shifts in the interference spectra of a porous semiconductor substrate such as a silicon substrate make possible the detection, identification and quantification of small molecules. While such a biological sensor is certainly useful, its sensitivity is lacking in that detection of a reflectivity shift is complicated by a broad peak rather than one or more sharply defined reflectance dips.

Additionally, although porous silicon (“PSi”) microcavity structures of various pore sizes have been discovered (PROPERTIES OF POROUS SILICON (Leigh Canham ed., 1997); LEHMANN & VOLKER, ELECTROCHEMISTRY OF SILICON (2002), structures with pore sizes between 100 nm and 300 nm, which is advantageous for sensing large molecules, have not been intensively studied. Most of the PSi microcavity sensors reported are etched from a highly doped p-type silicon substrate, which usually leads to a mesoporous structure that has a pore size from 10 nm to 50 nm. Mesoporous microcavities may be used for detecting small objects, such as gas, chemicals, and short DNA segments, but is not useful for sensing larger molecules (e.g., protein). Although post-etching treatments (e.g., KOH etching (Tinsley-Bown et al., “Tuning the Pore Size and Surface Chemistry of Porous Silicon for Immunoassays,” Phys. Stat. Sol. (a) 182(1):547-553 (2000))) or the use of a very high etching current density can increase the pore size to create larger pores (Janshoff et al., “Macroporous p-Type Silicon Fabry-Perot Layers. Fabrication, Characterization, and Applications in Biosensing,” J. Am. Chem. Soc. 120:12108-12116 (1998)), the stability and reproducibility of these methods are not practical for large scale manufacturing processes, and it is impossible to make complicated optical devices, such as multilayer structures, based on these methods.

The “classical” backside illumination techniques for manufacturing macroporous (pore size of 300 nm-20 μm) silicon on n-type silicon are well known (Lehmann & Föll, “Formation Mechanism and Properties of Electrochemically Etched Trenches in n-Type Silicon,” J. Electrochem. Soc. 137:653-659 (1990)). The minority carrier (holes), which is required for the formation of pores, can be generated by light from the backside of the wafer and focused on pore tips. With pore formation on n-type silicon, the pore density generally increases with increasing doping density because the doping concentration determines the pore-to-pore spacing. However, well-defined, straight and smooth macropores with pore sizes between 50 nm and 300 nm are hard to achieve using this light-assisted technique because, as the pore size and pore-to-pore distance reach the region below 300 nm, the doping level of the wafer is very high (>0.1 ohm-cm), thus the minority carrier (holes) diffusion length drops and the holes cannot reach the pore tips.

The present invention is directed to overcoming these and other deficiencies in the art.

### SUMMARY OF THE INVENTION

A first aspect of the present invention relates to a macroporous microcavity structure. The structure includes a porous semiconductor structure that has a central microcavity interposed between upper and lower layers, each of the upper and lower layers comprising strata of alternating higher and lower relative porosity, where the central microcavity comprises pores with an average pore size between about 20 nm and about 10 μm, and an average pore-to-pore distance of about 100 nm to about 30 μm.

A second aspect of the present invention relates to a biological sensor having a macroporous microcavity structure according to the first aspect of the present invention, and one or more probes coupled to the macroporous microcavity structure and characterized by an ability to bind to a target molecule, whereby a detectable change occurs in a refractive index of the biological sensor upon binding of the one or more probes to the target molecule.

A third aspect of the present invention relates to a detection device which includes: a biological sensor of the present invention; a source of illumination positioned to illuminate the biological sensor; and a detector positioned to capture light reflected from the biological sensor and to detect changes in a reflectance spectrum of the biological sensor.

A fourth aspect of the present invention relates to a method of preparing a macroporous microcavity structure including providing a crystalline semiconductor wafer, etching the wafer in a hydrofluoric acid based solution, with periodic changes in current density of between about 10 to about 40 mA/cm², under conditions effective to produce a macroporous microcavity structure according to the first aspect of the present invention.

A fifth aspect of the present invention relates to a method of making a biological sensor which detects a target molecule. This method includes: providing a primed porous semiconductor structure including a central layer interposed between upper and lower layers, each of the upper and lower layers including strata of alternating porosity; and exposing the primed porous semiconductor structure to a probe molecule including (i) one or more semiconductor structure-binding groups and (ii) one or more target-binding groups that bind to a target molecule, said exposing being carried out under conditions effective to bind the probe molecule to the primed porous semiconductor structure via a coupling agent or directly to the semiconductor structure upon displacement of the coupling agent, with the one or more target-binding groups remaining available for binding to the target molecule.

A sixth aspect of the present invention relates to a method of detecting a target molecule which includes: exposing a biological sensor of the present invention to a sample under conditions effective to allow binding of a target molecule in the sample to the one or more probes of the biological sensor; and determining whether the biological sensor has a reflectance spectrum that shifts following said exposing, whereby a shifted reflectance spectrum indicates the presence of the target molecule in the sample.

A seventh aspect of the present invention relates to a method of detecting the presence of pathogenic Escherichia coli in a sample which includes: exposing a sample to a biological sensor of the present invention with one or more probes binding to Intimin or fragments thereof; and determining whether the biological sensor emits a reflectance spectrum which shifts following said exposing, whereby a shifted reflectance spectrum indicates the presence of Intimin and, thus, pathogenic Escherichia coli in the sample.

A structure as described above, containing a central layer (microcavity) between upper and lower layers (Bragg reflectors), forms a microcavity resonator possessing a macroporous structure. This microcavity resonator solves several problems of other biological sensors using a simple porous silicon substrate (i.e., without the Bragg reflectors), one such problem being the simple porous silicon substrate's lack of fine sensitivity due to the substrate's small linear response range, and the presence of broad reflectance interference fringes that hinder differentiating between background noise and small, target-induced signal shifts. The microcavity resonator affords greater sensitivity in sensing the presence of biological targets. By confining the optical field in the central layer of the microcavity by two Bragg reflectors, the reflectance spectrum is composed of multiple sharp and narrow dips with FWHM values of about 3 nm. Upon a refractive index change, the reflectance spectrum shifts, thereby generating a large, detectable differential signal.

### BRIEF DESCRIPTION OF THE DRAWINGS

FIG. 1 is a schematic diagram of a porous semiconductor structure. The one-dimensional photonic bandgap device has a PSi sensing layer between two PSi Bragg mirrors. Reflected light, with a reflectance spectrum with narrow resonances, shifts when the target biological specie binds within the structure, changing its refractive index.

FIG. 2 illustrates schematically a microarray detector formed from a biological sensor of the present invention.

FIG. 3 illustrates schematically a detection device of the present invention which includes, as a component thereof, a biological sensor of the present invention.

FIGS. 4A-I are top view (4A, 4C, and 4G) and cross-sectional (4B, 4D, and 4H) scanning electron microscopy (SEM) images (4A-F), and pore-to-pore distance histograms (4G-I) of macropores etched on n-type silicon wafers with different resistivities: 0.001 Ω-cm (4A-B), 0.01 Ω-cm (4C-D), and 0.1 Ω-cm (4E-F). FIGS. 4G, 4H, and 4I, respectively, are histograms of these macropores. The top surface of these samples was mechanically polished to remove the several 100 nm thick top layers described in Example 11. The macropores shown in FIGS. 4A-D were etched using an electrolyte with 6% HF.

FIGS. 5A-B are top view (5A) and cross-sectional (5B) SEM image of a mesoporous silicon microcavity with pore size approximately 20 nm. It was formed in a highly doped p-type silicon substrate (0.01 ohm-cm) using an electrolyte with 15% HF in ethanol.

FIGS. 6A-B are a top view (6A) and cross-sectional view (6B) SEM image of the microcavity of Example 3.

FIG. 7 is a top view SEM image of a very large macroporous structure with a pore size of approximately 2 μm. In the SEM images, the darker regions represent the void space and the bright area is the silicon skeleton.

FIG. 8 is a graph of the current density, Jₘ needed to obtain straight and smooth macropores as a function of the HF concentration for n-type silicon wafers with a resistivity of 0.01 Ω-cm. Above the curve, electropolishing takes place; below the curve, branchy mesopores are formed. When the current density equals Jₘ, macropores with smooth pore walls are formed.

FIG. 9 is a graph of the effective refractive index of PSi as a function of the porosity at the wavelength of 800 nm. The black curve represents n_{void}=1 and the grey curve represents n_{void}=1.3.

FIG. 10 is a schematic diagram of PSi formation. Etching occurs only at the pore tips where the holes (h+) are focused by the electric field.

FIG. 11 is a graph of porosity as a function of the etching current density. This data was obtained from highly doped n-type silicon substrate using 5% HF etching solution.

FIGS. 12A-F are cross-sectional SEM images showing how a multilayer stack is formed from the top to the bottom when a square-waved current density is applied. The porosity of each layer is determined by the magnitude of the current density and the thickness is determined by the duration of the current pulse. FIGS. 12A-B are cross-sectional SEM images of a multilayer structure formed in highly doped n-type silicon (0.01 ohm-cm) using an electrolyte with 6% HF. The current densities are 40 mA/cm² and 15 mA/cm². The interface between two distinct layers is shown in FIG. 12B. FIGS. 12C-D show multilayers formed by current densities of 40 mA/cm² and 25 mA/cm². FIGS. 12E-F show multilayers formed by current densities of 40 mA/cm² and 35 mA/cm².

FIG. 13 is a graph illustrating the measured pore-to-pore distance and pore-wall thickness as a function of substrate resistivity from highly doped n-type substrates. The full line represents a width of twice the space-charge region (SCR), and the dashed line is a guide to the eye.

FIGS. 14A-E are cross sectional SEM images of the interface between two microcavity layers produced by different current densities, as labeled in the insets. The top layers were etched with a current density of 40 mA/cm². The morphology of the second layer strongly depends on the current density. As the current density decreased from 40 mA/cm² to 10 mA/cm², the pore diameter decreased from approximately 120 nm to 20 nm, and the tendency to form side pores increases. FIG. 14F is a graph showing the dependence of porosity on current density. A wide range of porosities can be achieved with the same wafer using the same electrolyte by altering the current density.

FIG. 15 is a cross-sectional SEM image of a microcavity structure containing layers with a high contrast in porosity. The microcavity structure was etched with an alternating current density of 40 mA/cm² and 10 mA/cm².

FIGS. 16A-B are a top-view SEM image (16A) of two layers with different porosities (˜80% and 50%) and a schematic diagram (16B) illustrating how the sample was polished to obtain the image shown in FIG. 16A.

FIGS. 17A-B are a graph of the simulation of the red-shift in the reflectance spectrum due to a 3% increase of refractive index inside the pores (17A); and as a function of pore size (16B). Each curve in FIG. 17B represents a different thickness (L) of the coating layer with n=1.42. The porosities of the layers used in all the calculations were fixed at 80 and 70%. For a given thickness of the coating (shaded area), the effective refractive-index change of a layer with small pores (inset A) is higher than that of a layer with large pores (inset B), which causes a larger shift in the spectrum. For a given pore size, the thicker the coating, the larger the shift.

FIG. 18 is a graph of a simulated red-shift. Solid diamonds: Red shift of the microcavity as a function of the number of periods in the Bragg mirrors. In the simulation, the resonance wavelength of the microcavity is at 800 nm and Δnₚₒᵣₑ=0.03. The optical thickness of the defect layer is one half wavelength. Open squares: Δλ/L as a function of the number of periods in the Bragg mirror.

FIG. 19 is a graph of a simulated red-shift. Solid diamonds: Red shift of the resonance as a function of the resonance wavelength. Open squares: Δλ/L as a function of resonance wavelength. In the simulation Δnₚₒᵣₑ=0.03, and the optical thickness of the defect layer is one half wavelength.

FIG. 20 is a graph of a simulated red-shift. Solid diamonds: Red shift of the resonance dips as a function of the defect layer thickness. Open squares: Δλ/L as a function of the defect layer thickness. In the simulation, Δnₚₒᵣₑ=0.03, and the center wavelength of the Bragg mirrors is 800 nm.

FIG. 21 is a graph of a simulation of Δλ as a function of the change of effective refractive index inside the pores (Δnₚₒᵣₑ).

FIGS. 22A-C are graphs relating to the red-shift upon binding of layers of varying thickness. The microcavity reflectance spectrum red-shift upon binding is illustrated in FIG. 22A. FIG. 22B shows the simulation of the microcavity spectrum red-shift as a function of the coating layer optical thickness (L=t×n_{layer}) for different pore sizes. The inset illustrates the coating of a thin layer on the pore wall. FIG. 22C shows the red-shift of the spectra with a sub-angstrom coating thickness.

FIGS. 23A-D are top view (23A, 23C) and cross sectional (23B, 23D) SEM images of a mesoporous silicon microcavity. The microcavity shown in FIGS. 23A-B has a 20 nm pore size and was etched in (100) p-type (0.01 ohm-cm) silicon wafers using a solution of 15% HF in ethanol. The microcavity shown in FIGS. 23C-D has a 120 mn pore size etched in (100) n-type (0.01 ohm-cm) silicon wafers using a solution containing 5.5% HF in water. These PSi microcavities consist of two Bragg mirrors (a periodic stack of layers with two different porosities and quarter-wavelength optical thickness) and a defect layer (half-wavelength optical thickness).

FIGS. 24A-B are graphs of the shift in reflectance at various APTES concentrations. FIG. 24A shows the red shift increase as the concentration of APTES increases for both mesoporous and macroporous silicon microcavities. The red shift saturates when one monolayer of APTES is formed inside the pores. FIG. 24B shows the red shift increase due to the binding of a two-layer coating made of glutaraldehyde and APTES. A fixed amount of glutaraldehyde was applied to sensors that were treated with different APTES concentrations. The red shift saturates when two layers of molecules completely coat the pores.

FIG. 25 is a graph of the red shift of microcavities due to the presence of a thin coating layer, as a function of pore size and layer thickness. The solid curves are the calculated red shifts as a function of the pore size using t=8 Å and 15 å thick coating layers with n_{layer}=1.46. The data points are the measured red shift for mesoporous (20 nm) and macroporous (120 nm) microcavities after coating of APTES and APTES+glutaraldehyde. The error bars are from multiple trials.

FIGS. 26A-C are cross sectional SEM images of a macroporous silicon microcavity (high-porosity layers formed using a current density of 40 mA/cm², low-porosity layers formed using a current density of 34 mA cm⁻²). The optical thickness of the defect layer sandwiched between the Bragg mirrors is one half wavelength. FIG. 26B is of the top Bragg mirror (10 periods) of the microcavity showing the complete opening of the pores. FIG. 26C is a cross sectional SEM image of a mesoporous silicon microcavity.

FIGS. 27A-B are graphs of the reflectance spectra of the microcavities shown in FIGS. 26A-C. FIG. 27A is a graph showing the measured (black) and simulated (gray) reflectance spectrua (calibrated to an aluminum mirror) of the microcavity depicted in FIGS. 26A-B. FIG. 27B is the reflectance spectrum of the mesoporous microcavity shown in FIG. 26C.

FIGS. 28A-F are SEM images of microcavity pores. FIGS. 28A-B are cross sectional (28A) and top view (28B) SEM images of a macroporous silicon layer formed with a current density of 40 mA cm⁻². The pore openings are smaller in the top few 100 nm. FIGS. 28C-D are cross sectional (28C) and top view (28D) SEM images of a silicon wafer surface after electropolishing (using a pulse of 250 mA cm⁻² with a 2 s duration) the entire porous layer shown in FIGS. 28A-B. FIGS. 28E-F are cross sectional (28E) and top view (28F) SEM images of a macroporous silicon layer etched using the substrate shown in FIGS. 28C-D. The pores are completely opened at the top. FIG. 28G is a schematic depiction of the defect pattern transformation process described in Example 11.

FIG. 29 is a cross sectional SEM micrograph of a microcavity.

FIG. 30 is a graph showing the reflectance spectrum of the microcavity depicted in FIG. 29.

FIG. 31 is cross sectional SEM image of a microcavity infiltrated with latex spheres with a maximum diameter of 10-60 nm.

FIG. 32 is a graph of the red-shift of the microcavity reflectance spectrum due to the infiltration of IgG (150 kDa). The total amount of red-shift is related to the concentration of the IgG solution on the sensor. The error bars represent results from multiple trials.

FIGS. 33A-C are graphs relating to the red-shift of the microcavity reflectance spectrum due binding of biotin and streptavidin. FIG. 33A shows the dependence of the total red-shift on the concentration of biotin applied on the sensor. FIG. 33B is the reflectance spectrum before and after exposure to streptavidin. A 10 nm red-shift was detected after the sensor was exposed to the target. The gray curve is the reflectance spectrum of the sensor with biotin. The black curve is the reflectance spectrum after the sensor was exposed to streptavidin (1 mg/mL⁻¹). FIG. 33C is a plot of the red-shift due to specific binding of streptavidin as a function of the biotin surface coverage.

FIG. 34 is a schematic diagram of the multiple layers of biomolecular interactions occurring inside the macropores of a one-dimensional micro cavity.

FIG. 35 is a graph of the red-shift upon exposure to rabbit (“Rabbit IgG”) and goat (“Goat IgG”) IgG. A 6 nm red-shift was detected when the sensor was exposed to the target molecule Rabbit IgG. When the sensor was exposed to Goat IgG, the red-shift was extremely small.

FIGS. 36A-D are cross-sectional (36A-B) and top view (36C) SEM images of a macroporous silicon microcavity and its reflectance spectrum (36D) with pore size approximately 120 nm.

FIG. 37 is a graph of the red shift of the reflectance spectra of the macroporous silicon microcavity of Example 17 as a function of the Tir-IBD concentration. The total volume of the solution applied to each sensor is 50 μl.

FIG. 38 is a graph of the red shifts of the sensors that were functionalized with different Tir-IBD concentrations after the exposure to purified Intimin-ECD solutions with different concentrations from 5 μM to 60 μM.

FIG. 39 is a graph showing the dependence of the sensor red shift on the Inimin-ECD solution concentration. These sensors were functionalized with 1 mM Tir-IBD solutions.

FIG. 40 is a graph of the reflectance spectra with (black curve) and without (grey curve) a thin film (n_{film}=1.5, thickness=50 nm) on top of a microcavity. The presence of the thin film does not affect the position of the resonance dip, and only the side lobes are modified. A microcavity sensor can therefore operate in a dirty environment.

### DETAILED DESCRIPTION OF THE INVENTION

One aspect of the present invention relates to a biological sensor which includes a macroporous semiconductor structure and one or more probes coupled to the porous semiconductor structure. The macroporous semiconductor structure can be formed onto any suitable semiconductor substrate (e.g., on a chip, wafer, etc.), and either maintained thereon or removed therefrom.

The porous semiconductor structure includes a central layer (a microcavity) interposed between upper and lower layers, each of the upper and lower layers including strata of alternating porosity. The upper and lower layers form Bragg reflectors.

Semiconductors which can be used to form the porous semiconductor structure can be a single semiconductor material, a combination of semiconductor materials which are unmixed, or a mixture of semiconductor materials. By virtue of the Bragg reflectors (i.e., the upper and lower layers), the emitted reflectance spectrum is composed of multiple sharp and narrow peaks. The light can be in the visible portion of the electromagnetic spectrum (i.e., 350-800 nm), the infrared region (i.e., ≧800 nm), and the ultraviolet region (i.e., 50-350 nm). These wavelengths are only exemplary and can vary according to the type of semiconductor material(s) used to form the porous semiconductor structure, the thickness thereof, as well as the porosity and pore size thereof. Generally, the wavelength of the light is preferably larger than the pore size. With the macroporous semiconductor structure, longer wavelengths are preferred.

Preferred semiconductors which can be used to form the porous semiconductor structure include, without limitation, silicon and silicon alloys. The semiconductor is amenable to galvanic etching processes which can be used to form the porous structure. These semiconductor materials can include p-doped silicon (e.g., (CH₃)₂Zn, (C₂H₅)₂Zn, (C₂H₅)₂Be, (CH₃)₂Cd, (C₂H₅)₂Mg, B, Al, Ga, In), n-doped (e.g., H₂Se, H₂S, CH₃Sn, (C₂H₅)₃S, SiH4, Si₂H₆, P, As, Sb) silicon, intrinsic or undoped silicon, alloys of these materials with, for example, germanium in amounts of up to about 10% by weight, mixtures of these materials, and semiconductor materials based on Group III element nitrides.

Suitable semiconductors which can be used to form the porous semiconductor structure include, without limitation, those with a resistivity of about 0.001 to about 20 ohm-cm, preferably about 0.001 to about 1.0 ohm-cm, most preferably about 0.001 to about 0.02 ohm-cm.

Two primary advantages make porous silicon (or nanoscale silicon) an attractive material for biosensing applications. First, its enormous surface area ranges from about 90 m²/cm³ to about 783 m²/cm³ (Herino, “Pore Size Distribution in Porous Silicon,” in PROPERTIES OF POROUS SILICON 89 (Leigh Canham ed., 1997), which is hereby incorporated by reference in its entirety), which provides numerous sites for many potential species to attach (Lauerhaas et al., “Chemical Modification of the Photoluminescence Quenching of Porous Silicon,” Science 261(5128): 1567-1568 (1993), which is hereby incorporated by reference in its entirety). Second, its eye-detectable, room temperature luminescence spans the visible spectrum (Canham, “Silicon Quantum Wire Array Fabrication by Electrochemical and Chemical Dissolution of Wafers,” Appl. Phys. Lett. 57(10):1046-1048 (1990), which is hereby incorporated by reference in its entirety), which makes it an effective transducer.

The macroporous semiconductor structure can range in thickness from about 1 to about 30 microns. Typically, the thickness will vary inversely according to the desired porosity (i.e., higher porosity structures will be thicker than lower porosity structures) as well as according to the wavelength of light to be detected (i.e., structures which are used with shorter wavelength light can be thinner than structures which are used with longer wavelength light).

The pores (or cavities) in the macroporous semiconductor structure are typically sized in terms of their nominal “diameter” notwithstanding the fact that they are somewhat irregular in shape and vary in diameter from one strata to another. These diameters range from about 50 nm to about 10 μm, with diameters of about 50 nm to about 100 nm being preferred for visible light, and about 100 nm to about 10 μm being preferred for infrared light. The nominal pore diameter should also be selected based upon the size of the target molecule to be detected. The macroporous structures of the present invention are preferably characterized by an average pore size of between about 20 nm to about 2000 nm, more preferably about 50 nm to about 2000 nm, most preferably about 50 nm to about 300 nm, about 75 mn to about 225 nm, or about 80 nm to about 200 nm; substantially straight pores (i.e., uniformly parallel and typically normal to the porous semiconductor surface); and substantially smooth pores (i.e., with little or no side-branching porosity). The average pore-to-pore distance varies depending on the pore size, but is preferably about 100 nm to about 30 μm. Usually, the larger the pore size, the larger the pore-to-pore distance (see FIG. 13). For example, for microcavities with an average pore size of 75-80 nm or 150-200 nm, the pore-to-pore distances are, respectively, about 200 nm and about 250 nm. Preferably, the upper and center layer have substantially the same pore size, most preferably the upper, center, and lower layers have substantially the same pore size. However, embodiments in which the average pore size differs between layers are also contemplated. As used herein, pore size refers to the average dimension of the pores at the outer surface of the semiconductor structure. It is understood that the dimension of the pores varies throughout the depth of the structure. 10066] As noted above, the porosity of the structure, including its central layer, will vary inversely according to its thickness. Typically, the porosity of the central layer is about 50 to about 90 percent, although slightly lower or higher porosity may be attained for specific applications. For most applications, the porosity is preferably about 65 to about 85 percent. The central microcavity preferably has an optical thickness of λ/2, or λ (although optical thickness increased by a factor of λ/2 can also be used (see Example 9, infra)).

The upper and lower layers individually contain strata of alternating porosity, i.e., higher and lower porosity strata, relative to the adjacent strata. The upper layer and lower layer can be symmetrical (i.e., having the same configuration, including the number of strata) or they can be different (i.e., having different strata configurations in number and/or porosity). Typically, the total number of strata is six or more (i.e., three or more high porosity strata and three or more low porosity strata in an alternating configuration). In one preferred embodiment, each of the upper and lower layers of the microcavity structure has between about four to about fifteen strata of alternating porosity.

The lower porosity strata simply have a porosity which is less than the porosity of their adjacent higher porosity strata. The lower porosity strata preferably have a porosity of about 30 to about 80 percent for sensing smaller targets, and about 60 to about 80 percent for sensing larger targets. The higher porosity strata preferably have a porosity of about 30 to about 80 percent, more preferably between about 60 to about 80 percent, for sensing larger targets; and about 30 to about 80 percent for sensing smaller targets. The porosity ratio of the higher porosity stratum to lower porosity stratum is preferably between about 1.05 and about 3.0. As the porosity ratio approaches 1, a greater number of periods of higher/lower porosity stratum is needed to achieve suitable signal resonance.

Within each of the upper and lower layers on opposite sides of the central layer, the low porosity and high porosity strata need not be the same throughout. Thus, different low porosity strata and different high porosity strata can be present within a single upper or lower layer. It is preferable, however, for the low porosity strata and the high porosity strata to be substantially consistent within the upper and lower layers. Preferably, the individual stratum have an optical thickness of λ/4 (or factors thereof, e.g., 3λ/4, 5λ/4, etc.).

The porous semiconductor structure can be formed by electrochemical etching. For example, an etching solution is prepared by adding a volume of pure ethanol to an aqueous solution of HF, e.g., from about 3% to about 50% by weight HF, more preferably about 3.5% to about 10%. Basically, the semiconductor material is introduced into the etching solution and a platinum or other inert cathode is provided in solution. The etching cell is then exposed to an anodic current (Canham Canham, “Silicon Quantum Wire Array Fabrication by Electrochemical and Chemical Dissolution of Wafers,” Appl. Phys. Lett. 57(10):1046-1048 (1990); and Bsiesy et al., “Photoluminescence Of High Porosity And Of Electrochemically Oxidized Porous Silicon Layers,” Surface Science 254:195-200 (1991), each of which is hereby incorporated by reference in its entirety). The anodic current densities can be selected by one of ordinary skill in the art according to the type of semiconductor material, the degree of porosity which is desired in the final porous structure, etc. Specifically, to create the Bragg reflectors a substantially square-waved current is applied over a time course to afford a higher rate of etching (creating the high porosity strata) and a lower rate of etching (creating the low porosity strata).

According to one embodiment, the porous semiconductor structure is prestructured to eliminate the nucleation layer that may form during etching. Prestructuring may be carried out by etching a sacrificial layer on the porous semiconductor material and then electropolishing the sacrificial layer at a high current and short pulse to produce a surface with a plurality of defects. The prestructured surface is then etched as described above to produce the microcavity. The result of this nucleation and electropolishing step prior to etching to form the Bragg mirrors and microcavity, is that the pore openings are substantially the same as the pore dimension of the first stratum of the upper Bragg mirror. This process is particularly preferred when using highly doped (i.e. 0.001-0.02 ohm-cm) substrates.

After etching, the porous semiconductor structure is rinsed in ethanol and dried under a stream of inert gas (N₂) or an oxidative gas (O₂, O₃, or Br₂). Thereafter, the porous semiconductor structure can be hydrolyzed in air.

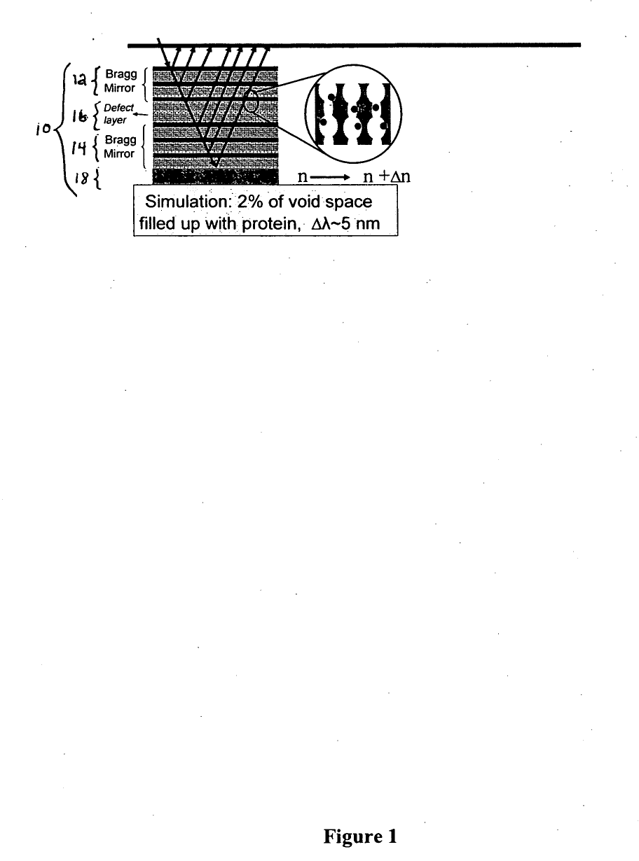

The resulting porous semiconductor structure has a configuration as illustrated in FIG. 1, with the upper layer 12 and the lower layer 14 on opposite sides of the central layer 16 which is the microcavity. The porous semiconductor structure 10 is formed on a substrate 18 (e.g., c-Si), and via electropolishing conditions can be removed from the bulk substrate.

To form a biological sensor from the porous semiconductor structure, one or more probes which bind to a target molecule are coupled to the porous semiconductor structure. The one or more probes each include (i) one or more semiconductor-binding groups which enable them to be coupled to the semiconductor structure (either directly or via a coupling agent) and (ii) one or more target-binding groups that bind to a target molecule. Although not limited to such, the one or more semiconductor-binding groups are typically hydroxyl groups. The one or more target-binding groups can include, without limitation, an amino group, a thiol, a hydroxyl, an alkyl chain, an ester, a carboxylic acid, an aromatic, a heterocycle, or a combination thereof. Alternatively, the one or more target-binding groups can be not just a single functional group but a complex protein-protein interaction, antibody-antigen recognition, etc.

Suitable probes generally include, without limitation, non-polymeric small molecules, polypeptides or proteins, and oligonucleotides.

Exemplary non-polymeric small molecules include, without limitation: avidin, biotin, peptido-mimetic compounds, and vancomycin. One class of peptido-mimetic compounds is disclosed in U.S. patent application Ser. No. 09/568,403 to Miller et al., filed May 10, 2000, each of which is hereby incorporated herein by reference in its entirety. A preferred peptido-mimetic compound which binds to lipopolysaccharide is a tetratryptophan ter-cyclopentane as disclosed in the above-noted application to Miller et al. Other peptidomimetic compounds can also be employed.

Exemplary polypeptides include, without limitation, a receptor for cell surface molecule or binding-effective fragments thereof; a lipid A receptor; an antibody or functional fragment thereof; peptide monobodies of the type disclosed in U.S. patent application Ser. No. 09/096,749 to Koide, filed Jun. 12, 1998, and U.S. patent application Ser. No. 10/006,760 to Koide, filed Nov. 19, 2001, each of which is hereby incorporated by reference in its entirety; a lipopolysacchardide-binding polypeptide; a peptidoglycan-binding polypeptide; a carbohydrate-binding polypeptide; a phosphate-binding polypeptide; a nucleic acid-binding polypeptide; and polypeptides which bind organic warfare agents such as tabun, sarin, soman, GF, VX, mustard agents, botulinium toxin, Staphylococcus entertoxin B, and saitotoxin.

Exemplary oligonucleotide probes can by DNA, RNA, or modified (e.g., propynylated) oligonucleotides of the type disclosed in Barnes & Turner, “Long-range Cooperativity in Molecular Recognition of RNA by Oligodeoxynucleotides with Multiple C5-(1-propynyl) Pyrimidines,” J. Am. Chem. Soc. 123(18):4107-4118 (2001), and Barnes et al., “Long-range Cooperativity Due to C5-Propynylation of Oligopyrimidines Enhances Specific Recognition by Uridine of Ribo-adenosine Over Ribo-guanosine,” J. Am. Chem. Soc. 123(37):9186-9187 (2001), each of which is hereby incorporated by reference in its entirety. The oligonucleotide probes can be any length which is suitable to provide specificity for the intended target. Typically, oligonucleotide probes which do not contain modified nucleotides will be at least about 12 to about 100 nucleotides in length. For oligonucleotides which contain modified bases, oligonucleotides should be at least about 7 nucleotides in length, up to about 100 nucleotides in length. Other types of nucleic acid probes can be RNA or DNA aptamers that possess binding activity for a molecular target.

Target molecules that can be bound by the one or more probes include, without limitation: proteins (including without limitation cell surface markers, enzymes, antibodies or fragments thereof), glycoproteins, peptidoglycans, carbohydrates, lipoproteins, a lipoteichoic acid, lipid A, intimin, phosphates, nucleic acids which are expressed by certain pathogens (e.g., bacteria, viruses, multicellular fungi, yeasts, protozoans, multicellular parasites, etc.), or organic compounds such as naturally occurring toxins or organic warfare agents, etc. These target molecules can be detected from any source, including food samples, water samples, homogenized tissue from organisms, etc. Moreover, the biological sensor of the present invention can also be used effectively to detect multiple layers of biomolecular interactions, termed “cascade sensing.” Thus, a target, once bound, becomes a probe for a secondary target.

A number of strategies are available for attaching the one or more probes to the surface of the porous semiconductor structure, depending upon the type of probe which is ultimately to be attached thereto. Because of the porosity of the semiconductor structure, the probes can be bound to the exposed surfaces of the semiconductor structure throughout its central layer and its upper and lower layers.

The available strategies for attaching the one or more probes include, without limitation, covalently bonding a probe to the surface of the semiconductor structure, ionically associating the probe with the surface of the semiconductor structure, adsorbing the probe onto the surface of the semiconductor structure, or the like. Such association can also include covalently or noncovalently attaching the probe to another moiety (of a coupling agent), which in turn is covalently or non-covalently attached to the surface of the semiconductor structure.

Basically, the oxidized and hydrolyzed surface of the semiconductor structure is first functionalized (i.e., primed) with a coupling agent which is attached to the surface thereof. This is achieved by providing a coupling agent precursor and then covalently or non-covalently binding the coupling agent precursor to the surface of the semiconductor structure. Once the semiconductor surface has been primed, the probe is exposed to the primed semiconductor surface under conditions effective to (i) covalently or non-covalently bind to the coupling agent or (ii) displace the coupling agent such that the probe covalently or non-covalently binds directly to the semiconductor surface. The binding of the probe to the semiconductor structure is carried out under conditions which are effective to allow the one or more target-binding groups thereon to remain available for binding to the target molecule.

Suitable coupling agent precursors include, without limitation, silanes functionalized with an epoxide group, a thiol, or an alkenyl; and halide containing compounds.

Silanes include a first moiety which binds to the surface of the semiconductor structure and a second moiety which binds to the probe. Preferred silanes include, without limitation, 3-glycidoxypropyltrialkoxysilanes with C1-6 alkoxy groups, trialkoxy(oxiranylalkyl)silanes with C2-12 alkyl groups and C1-6 alkoxy groups, 2-(1,2-epoxycyclohexyl)ethyltrialkoxysilane with C1-6 alkoxy groups, 3-butenyl trialkoxysilanes with C1-6 alkoxy groups, alkenyltrialkoxysilanes with C2-12 alkenyl groups and C1-6 alkoxy groups, tris[(1-methylethenyl)oxy]3-oxiranylalkyl silanes with C2-12 alkyl groups, [5-(3,3-dimethyloxiranyl)-3-methyl-2-pentenyl]trialkoxysilane with C1-6 alkoxy groups, (2,3-oxiranediyldi-2,1-ethanediyl)bis-triethoxysilane, trialkoxy[2-(3-methyloxiranyl)alkyl]silane with C1-6 alkoxy groups and C2-12 alkyl groups, trimethoxy[2-[3-(17,17,17-trifluoroheptadecyl)oxiranyl]ethyl]silane, tributoxy[3-[3-(chloromethyl)oxiranyl]-2-methylpropyl]silane, and combinations thereof Silanes can be coupled to the semiconductor structure according to a silanization reaction scheme shown in FIG. 9A of International Patent Application No. PCT/US02/05533 to Chan et al., which is hereby incorporated by reference in its entirety, the conditions for which are well known to those of skill in the art and described in the above-noted Chan et al. application.

Halides can also be coupled to the semiconductor structure according to the reaction scheme set forth in FIG. 9B of International Patent Application No. PCT/US02/05533 to Chan et al., which is hereby incorporated by reference in its entirety, the conditions for which are well known to those of skill in the art.

Thereafter, the one or more probes are bound to the semiconductor structure according to the type of functionality provided by the coupling agent. Typically, probes are attached to the coupling agent or displace the coupling agent for attachment to the semiconductor structure in aqueous conditions or aqueous/alcohol conditions.

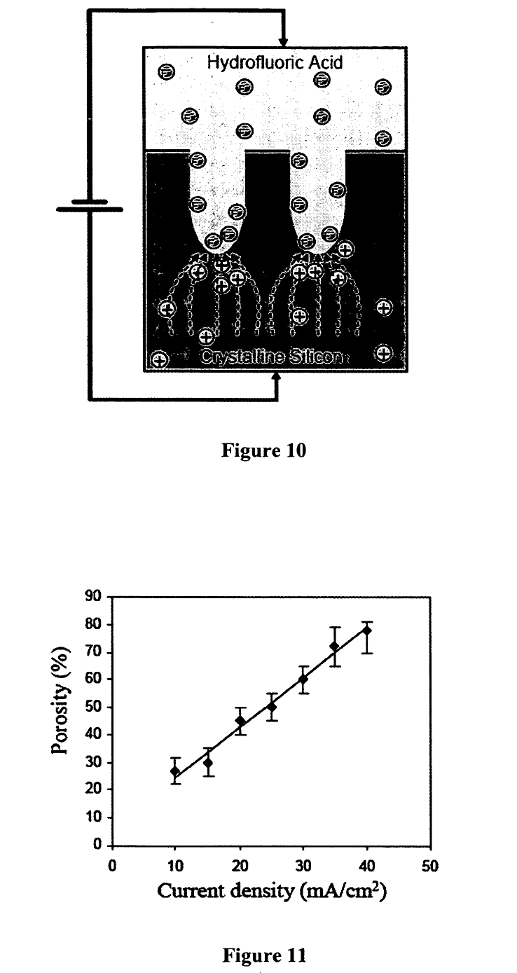

Epoxide functional groups can be opened to allow binding of amino groups according to the reaction scheme set forth in FIG. 10A of International Patent Application No. PCT/US02/05533 to Chan et al., which is hereby incorporated by reference in its entirety, the conditions for which are well known to those of skill in the art and described in the above-noted Chan et al. application. Epoxide functional groups can also be opened to allow binding of thiol groups or alcohols according to the reaction scheme set forth in FIGS. 10B-C of International Patent Application No. PCT/US02/05533 to Chan et al., which is hereby incorporated by reference in its entirety, respectively, the conditions for which are well known to those of skill in the art.

Alkenyl functional groups can be reacted to allow binding of alkenyl groups according to the reaction scheme set forth in FIG. 10D of International Patent Application No. PCT/US02/05533 to Chan et al., which is hereby incorporated by reference in its entirety, the conditions for which are well known to those of skill in the art.

Where a halide coupling agent is employed, the halide coupling agent is typically displaced upon exposing the primed semiconductor structure to one or more probes which contain alcohol groups as the semiconductor-binding groups. The displacement can be carried out according to the reaction scheme set forth in FIG. 10E of International Patent Application No. PCT/US02/05533 to Chan et al., which is hereby incorporated by reference in its entirety, the conditions for which are well known to those of skill in the art.

Where the one or more probes contain two or more target-binding groups, it is possible that the target-binding groups may also interact and bind to the primed surface of the semiconductor structure. To preclude this from occurring, the primed porous semiconductor structure can also be exposed to a blocking agent. The blocking agent essentially minimizes the number of sites where the one or more probes can attach to the surface of the semiconductor structure. Exposure to the blocking agent can be carried out prior to exposing the primed surface of the semiconductor structure to the probes or simultaneous therewith, although simultaneous exposure is generally preferred. The blocking agents can be structurally similar to the probes except that they lack a target-binding group or the blocking agents can simply be simple end-capping agents. By way of example, an amino acid alkyl ester (e.g., glycine methyl ester, glycine ethyl ester, 3-alanine methyl ester, etc.) blocking agent can be introduced to an epoxide-functionalized semiconductor structure surface as shown in FIG. 10A of International Patent Application No. PCT/US02/05533 to Chan et al., which is hereby incorporated by reference in its entirety, for attaching a probe to the coupling agent, except with the amino group of glycine opening the epoxide ring and covalently binding to the coupling agent.

Detectable changes in the reflectance spectrum of the biological sensor occur upon binding of the one or more probes to the target molecule will depend on the sensitivity of the type of detector employed. Many widely available detectors afford the detection of reflectance spectrum dips via shifts of about 2 nm or greater. The Q-factor of a microcavity, which is defined as Q=λ/Δλ, where λ is the resonance center wavelength and Δλ is the full width at half maximum of the resonance dip, is used to evaluate how effectively light is confined within a photonic bandgap structure. The larger the Q, the more efficiently light is confined inside the cavity. In sensing applications where the shift of the spectrum is monitored, increasing the Q of the microcavity will increase the ability to resolve a small wavelength shift. Thus, the Q of the sensor should be as high as possible to increase the sensitivity. Preferably, the macroporous microcavity structures of the present invention have a Q-factor of about 50 to about 100.

The microcavity design has an advantage over the single layer structure, in that clear “on/off” digital states exist. When the refractive index (n), of the surrounding material increases from n=1.0 to n=1.03, the reflectivity spectrum red-shifts. A red-shift is predicted because the pores are filled with a material of larger refractive index. At a fixed wavelength under investigation, no “on/off” states are seen in the single layer case. However, for a microcavity structure of the present invention, a distinct “on/off” state is present. At 687 nm, the digital microcavity sensor produces a “0” output signal when the refractive index of the sensing material is 1.03, and produces a “1” output signal when the refractive index changes to 1.0. This is one of the major advantages of using porous-semiconductor material microcavity structures for sensor applications. This is particularly useful when non-quantitative detection is desired.

When quantitative detection is desired, the size of the reflectance spectrum shift correlates with the amount of bound target molecule that appears in the pores following exposure thereof to a sample containing the target molecule. Knowing the maximal amount of target molecule that can bind to a biological sensor of the present invention, i.e., the number of available target-binding groups on the surface-bound probes and the maximal shift that can be achieved under those conditions, it is possible to predict a quantitative concentration of the target molecule in a sample based on the detected shift that occurs, as described in Example 9, infra.

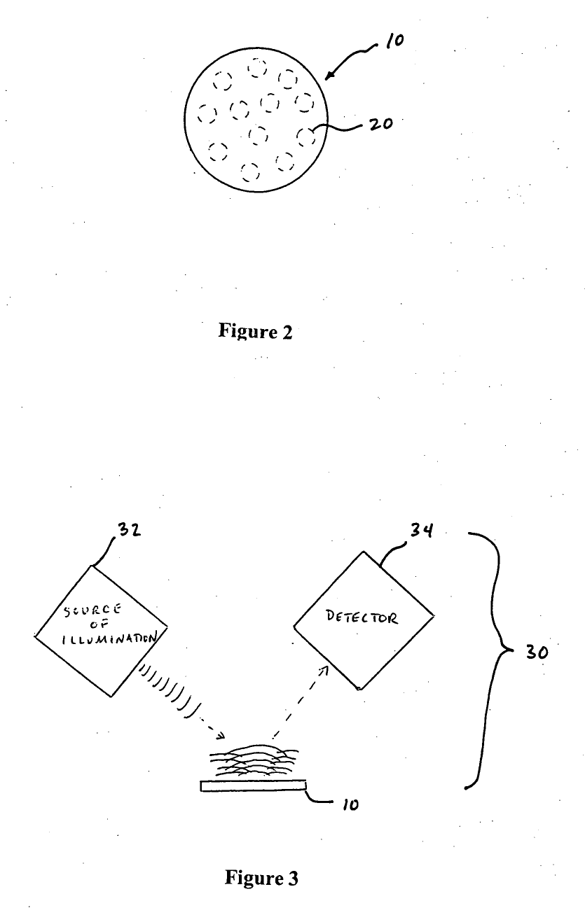

By virtue of the biological sensors of the present invention to afford a uniquely well defined reflectivity shift upon binding to a target, the biological sensors can be utilized in the form of a microarray detector, schematically illustrated in FIG. 2, which is hereby incorporated by reference in its entirety. Thus, the microarray detector is a biological sensor of the present invention which includes a number of locations or zones thereon which have been functionalized to include the one or more probes. The one or more probes at each of these locations can be the same (binding to the same target) or different (binding to different targets).

As shown in FIG. 3, which is hereby incorporated by reference in its entirety, the biological sensor of the present device is intended to be utilized as a component of a detection device which also includes a source of illumination (e.g., argon, cadmium, helium, or nitrogen laser and accompanying optics) positioned to illuminate the biological sensor and a detector (e.g., collecting lenses, monochrometer, and detector) positioned to capture reflectance from the biological sensor and to detect changes in the reflectance spectrum of the biological sensor. The source of illumination and the detector can both be present in a spectrometer. A computer with an appropriate microprocessor can be coupled to the detector to receive data from the spectrometer and analyze the data to compare the reflectance spectra before and after exposure of the biological sensor to a target molecule.

A further aspect of the present invention relates to a method of detecting a target molecule in a sample. Basically, a biological sensor of the present invention is exposed to a sample under conditions effective to allow binding of a target molecule in the sample to the one or more probes of the biological sensor. After such exposure, it is determined whether the biological sensor is characterized by a reflectance spectrum that has shifted, indicating the presence of the target molecule in the sample.

To determine whether a shift has occurred, a first (baseline) reflectance spectrum is measured prior to exposure to a sample. After exposure to the sample, a second reflectance spectrum is measured, and the first and second spectra are compared. A shift as little as about 1 or 2 nm can indicate the presence of the target in the sample. Typically, the size of the shift will depend on the size of the target to be recognized, its concentration within the sample, the duration of exposure, and the quantity of probe present on the surface. This determination can be performed using the detection device as described above.

As noted above, the biological sensor (and detection device containing the same) can be used to detect the presence of a pathogen in a sample. Samples which can be examined include blood, water, a suspension of solids (e.g., food particles, soil particles, etc.) in an aqueous solution, or a cell suspension from a clinical isolate (such as a tissue homogenate from a mammalian patient).

By way of example, one method of the present invention involves the detection of pathogenic Escherichia coli in a sample. This is achieved by exposing the sample to a biological sensor of the present invention which includes one or more probes that bind to Intimin or fragments thereof (e.g., extracellular Intimin domains). A preferred probe of this type is Tir or an Intimin-binding domain thereof as disclosed in Homer et al., “A Proteomic Biosensor For Enteropathogenic E. coli,” Biosens. Bioelectron. 21(8):1659-1663 (2006), which is hereby incorporated herein by reference in its entirety. Thereafter, a determination is made as to whether a shift in the reflectance spectrum has occurred (i.e., as described above), indicating the presence of Intimin and, thus, pathogenic E. coli in the sample. To ensure that any Intimin is available to bind to the probe, depending upon the pore size it may be desirable but not essential to treat the sample prior to its exposure to the biological sensor in a manner effective to disrupt the cellular membrane of E. coli in the sample, thereby releasing Intimin contained within the bacterial membrane. This can be achieved by chemical means which do not modify the structure of Intimin itself, by mechanical means (French press), by sonication, or freezing (and thawing).

Reflection of light at the top and bottom of the exemplary porous semiconductor structure results in an interference pattern that is related to the effective optical thickness of the structure. Binding of a target molecule to its corresponding probe, immobilized on the surfaces of the porous semiconductor structure, results in a change in refractive index of the structure and is detected as a corresponding shift in the interference pattern (i.e., the reflectance spectrum). The refractive index for the porous semiconductor structure in use is related to the index of the porous semiconductor structure and the index of the materials present (contents) in the pores. The index of refraction of the contents of the pores changes when the concentration of target species in the pores changes. Most commonly, the target is an organic species that has a refractive index that is larger than that of the semiconductor structure. The replacement of a species of lower index of refraction (air or other fluid medium) by another species of higher index of refraction (target species) would be expected to lead to an increase in the overall value for index of refraction. An increase in index should result in a shift in the interference pattern wavelengths to longer values; i.e., a bathochromic or “red” shift.

From all of the above, it should be appreciated that the biological sensor can be used with appropriate probes for purposes of defining protein-protein interactions for proteomics, defining molecular interaction partners involved in the regulation of gene transcription events, for genomic analysis, for metabonomic analysis, and in general for screening drugs to determine their interactions with particular proteins or nucleic acids, as well as for screening combinatorial libraries which bind to a particular probe (which itself can be a biochemical target for therapeutic or preventative treatments).

### EXAMPLES

The following examples are intended to illustrate, but by no means are intended to limit, the scope of the present invention as set forth in the appended claims.

### Example 1

### Fabrication of Macroporous Silicon Microcavity (Pores<300 nm) in n-Type Silicon

The general trend in n-type PSi is that the pore density increases as the substrate doping level increases (Theunissen, “Etch Channel Formation During Anodic Dissolution of n-Type Silicon in Aqueous Hydrofluoric Acid ,” J. Electrochem. Soc. 119:351-360 (1972); Lehmann et al., “On the Morphology and the Electrochemical Formation Mechanism of Mesoporous Silicon,” Mater. Sci. Eng. B 69(70):11-22 (2000); Lehmann & Föll, “Formation Mechanism and Properties of Electrochemically Etched Trenches in n-Type Silicon,” J. Electrochem. Soc. 137:653-659 (1990), which are hereby incorporated by reference in their entirety). However, only well-defined macropores with pore sizes larger than 300 nm (Schilling et al., “Optical Characterisation of 2D Macroporous Silicon Photonic Crystals With Bandgaps Around 3.5 and 1.3 μm,” Opt. Mater. 17(1-2):7-10 (2001); Lehmann & Gruning, “The Limits of Macropore Array Fabrication,” Thin Solid Films 297:13-17 (1997), which are hereby incorporated by reference in their entirety) and, very recently, 200 nm (Badel et al., “Formation of Ordered Pore Arrays at the Nanoscale by Electrochemical Etching of Highly Doped n-Type Silicon,” Superlattices Microstruct. 36:245-253 (2004), which is hereby incorporated by reference in its entirety) have been demonstrated. For substrates with doping concentrations larger than 10¹⁷ cm⁻³ (˜0.1 Ω-cm) that could lead to smaller macropores, mesopores have been observed (LEHMANN & VOLKER, ELECTROCHEMISTRY OF SILICON (2002), which is hereby incorporated by reference in its entirety).

The “classical” backside illumination techniques for manufacturing macroporous (pore size of 300 nm-20 μm) silicon on n-type silicon are well known (Lehmann & Föll, “Formation Mechanism and Properties of Electrochemically Etched Trenches in n-Type Silicon,” J. Electrochem. Soc. 137:653-659 (1990), which is hereby incorporated by reference in its entirety). However, well-defined, straight and smooth macropores with pore sizes between 50 nm and 300 nm cannot be reproducibly achieved using this light-assisted technique because, as the pore size and pore-to-pore distance reach the region below 300 nm, the doping level of the wafer is very high (>0.1 ohm-cm), thus the minority carrier (holes) diffusion length drops and the holes cannot reach the pore tips. By systematically investigating the dependence of pore formation on electrolyte composition and etching current density in highly doped n-type silicon, a method to achieve well-defined, straight and smooth macropores using an HF acid based aqueous solution on highly doped n-type wafers without light assistance has been discovered.

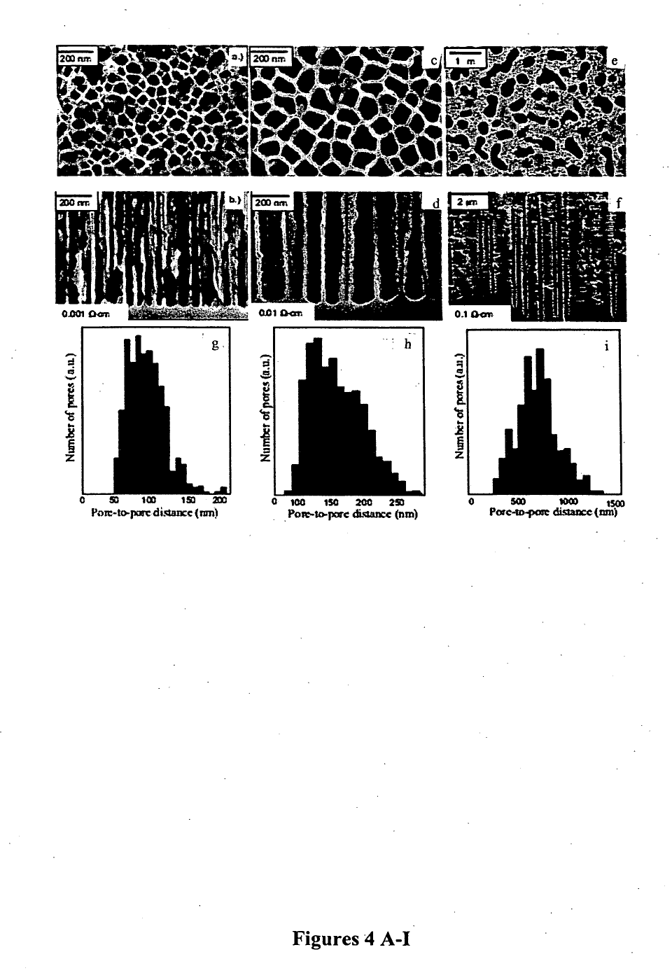

N-type silicon wafers with resistivity from 0.001 ohm-cm to 0.1 ohm-cm were included in this investigation. The electrolyte was 25 ml HF (49%), 200 ml H₂O, and 1 ml of surfactant (Wako NCW1001) to facilitate solution infiltration. Uniform straight and smooth macropores were found on wafers with resistivity smaller than 0.02 ohm-cm. For wafers with resistivity of 0.001 ohm-cm, pores with approximately 80 nm pore-to-pore spacing and 60 nm pore diameter were observed, as shown in FIGS. 4A and 4B. This pore diameter allows the infiltration of macromolecules such as immunoglobulin, and the formation of multiple layers of biomolecular interactions. For wafers with 0.01 ohm-cm resistivity, pores with approximately 150 nm pore-to-pore spacing and 120 nm pore diameter were obtained, as shown in FIGS. 4C and 4D. For wafers with resistivity of 0.1 ohm-cm, the pore diameter was around 300 nm with an average pore-pore distance of 700 nm, as shown in FIGS. 4E and 4F. However, in the 0.1 ohm-cm sample, the growth rate varied greatly from pore to pore, and the internal surface-area-to-volume ratio was very small, which makes these wafers less useful in sensing, especially optical sensing, applications. Histograms of the pore-to-pore distance in each of the microcavities generated using a MATLAB program based on the top-view scanning electron microscopy (SEM) images of the samples are shown in FIGS. 4G (0.001 ohm-cm microcavity), 4H (0.01 ohm-cm microcavity), and 4I (0.1 ohm-cm microcavity).

### Example 2

### Fabrication of Mesoporous Silicon Microcavity on p-Type Silicon

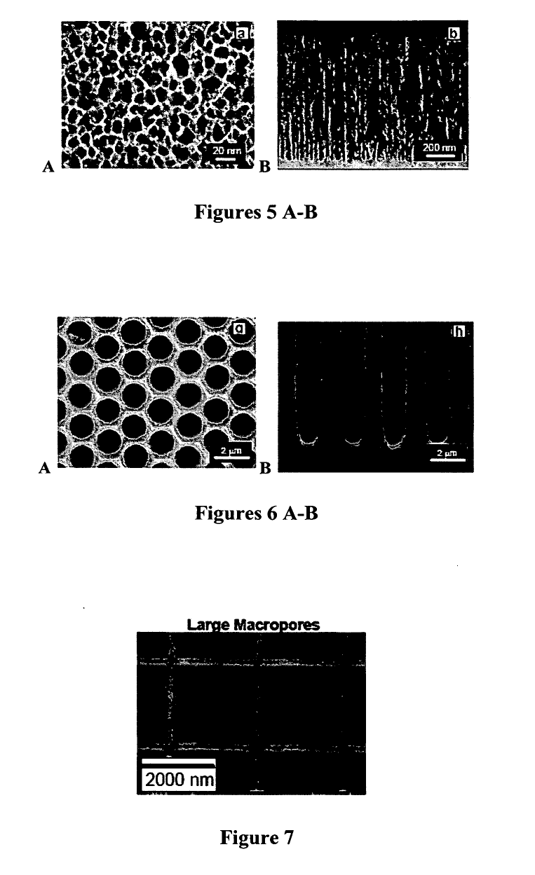

As shown in FIGS. 5A-B, a mesoporous silicon microcavity with an average pore diameter of approximately 20 nm was formed in a highly doped p-type silicon substrate (0.01 ohm-cm) using an electrolyte with 15% HF in ethanol. The mesopores formed in p+silicon substrates have highly branched pore walls. The 20 nm pore size is suitable for detection of small objects such as short DNA segments and low molecular weight molecules.

### Example 3

### Fabrication of Large Macroporous Silicon Structures

A large single-layer macroporous (1.5 μm) structure was etched from low doped p-type silicon (20 ohm-cm) using an HF/dimethylformamide electrolyte (Haurylau et al., “Optical Properties and Tunability of Macroporous Silicon 2-D Photonic Bandgap Structures,” Phys. Stat. Sol. A 202(8):1477-1481 (2005), which is hereby incorporated by reference in its entirety). As shown in FIGS. 6A-B, it has substantially straight and smooth pores.

Very large macropores (pore size of ˜2 μm) etched from low doped p-type silicon (20 ohm-cm) using an HF/dimethylformamide electrolyte are shown in FIG. 7 (Haurylau et al., “Optical Properties and Tunability of Macroporous Silicon 2-D Photonic Bandgap Structures,” Phys. Stat. Sol. A 202(8): 1477-1481 (2005), which is hereby incorporated by reference in its entirety). The large macropores are tunable from 500 nm to 10 microns, which is suitable for the detection of very large objects such as bacteria or virus.

### Example 4

### Microcavity Biosensor Fabrication

The macroporous microcavities used in Examples 13-15, infra, were electrochemically etched from n-type silicon of resistivity 0.01 Ω-cm (from Silicon Quest International Inc., arsenic doped, (100) orientation, single-side polished). The etching electrolyte was 200 mL deionized (DI) water, 25 mL HF (48% aqueous), and 1 mL surfactant (Wako NCW1001). A PSi sacrificial layer was first etched by applying a current density of j=40 mA cm⁻² for 30 seconds. Next, a 2 second duration pulse with j=250 mA cm⁻² was applied to detach the sacrificial layer from the substrate. Then, the sample was rinsed with DI water to remove the sacrificial layer. After this, the microcavity was fabricated using a current density alternating between 40 mA cm⁻² for 7 seconds and 34 mA cm⁻² for 5 seconds. The defect layer that separates the two Bragg mirrors was formed by applying j=40 mA/cm² for 14 seconds. After the formation of each layer, etching was stopped for 5 seconds before starting the next layer. The samples were rinsed with DI water and dried with nitrogen flow after anodization. The optical reflectance spectra were taken using an Ocean Optics HR 2000 spectrometer with a reflection probe R200-7 (6 illumination fibers around 1 read fiber). The typical etching area of the sensors was approximately 1.5 cm². The doping variation in the silicon wafer would produce inhomogeneity of the layers and thus decrease the Q factor. The experimental results show that sensors fabricated in the central part of 4 inch (1 in.=25.4 mm) wafers, where the measured resistivity variations are small, have a higher reproducibility and higher Q factor than sensors etched near the edge of the 4 inch wafer, where the measured resistivity variations are large.

After anodization, the PSi microcavities were thermally oxidized in a furnace at 900° C. under a constant oxygen flow for 3 minutes. Then the microcavities were silanized with 2% of 3-aminopropyltriethoxysilane (from Gelest Inc.) in H₂O and methanol (1:1) for 30 minutes. Next, the sensors were rinsed with DI water and baked in an oven at 100° C. for 10 minutes. After that, 2.5% of glutaraldehyde (from Sigma) in 20 mM HEPES buffer was applied to the sensors for 30 minutes. The sensors were then exposed to rabbit IgG (from Biocan Scientific Inc.) with various concentrations.

The microcavities used in the biotin-streptavidin experiment were prepared in substantially the same way. Biotin (from Pierce, Rockford, Ill.) in 50 mM PBS buffer (pH=7.5) was immobilized on the silanized sensors for 1 hour. Then the sensors were soaked/rinsed with PBS buffer for 10 minutes and dried with N₂ flow before the optical measurement. Next, streptavidin (from Pierce) in 20 mM potassium phosphate buffer (pH=6.5) was applied to the sensor for 1 hour, followed by soaking/rinsing with PBS buffer for 30 minutes and drying with N₂ flow before the optical measurement.

### Example 5

### Relationship Between Current Density and HF Acid Concentration in the Production of Substantially Straight and Smooth Macropores

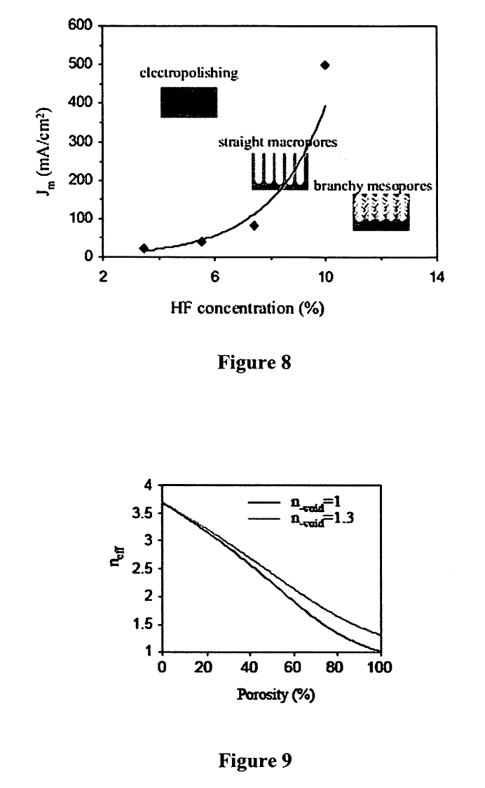

The pore diameter and morphology in highly doped n-type silicon are strongly dependent on the HF concentration and the current density, j, that is applied across the etching area. Substantially straight and smooth macropores are formed when j approaches the electropolishing current density Jₚₛ (electropolishing refers to the point at which silicon atoms are removed and no pores can be formed). The current density used for the formation of substantially straight and substantially smooth macropores is related to the HF concentration for a given wafer substrate, as shown in Table 1 (the wafer resistivity is 0.01 ohm-cm in this Example). This is consistent with observations of “classical” macropore formation with back-side illumination (Lehmann & Rönnebeck, “The Physics of Macropore Formation in Low-doped n-Type Silicon,” J. Electrochem. Soc. 140:2836-2843 (1993), which is hereby incorporated by reference in its entirety). FIG. 8 shows the relationship between the current density used to form smooth and straight macropores (Jₘ) and the HF concentration in n-type 0.01 Ω-cm wafers. As the HF concentration increases, Jₘ increases. Current densities far below Jₘ produce mesoporous structures, as discussed in Example 7, infra. Very high current densities are required to form straight and smooth macropores when the HF concentration is higher than 10%. An electrolyte that had a 5.5% HF concentration was used in Examples 1 and 4.

TABLE 1
Dependence of current density on HF concentration
for straight and smooth macropores

| | 3.5% (15 ml HF, | 5.5% (25 ml HF, | 7.5% (35 ml HF, |
|---|---|---|---|
| HF | 200 ml H₂O, | 200 ml H₂O, | 200 ml H₂O, |
| concentration | 1 ml surfactant) | 1 ml surfactant) | 1 ml surfactant) |
| Current | 20 mA/cm² | 40 mA/cm² | 80 mA/cm² |
| Density for | | | |
| Straight | | | |
| and Smooth | | | |
| Pores | | | |

### Example 6

### Effects of Porosity and Current Density on Macroporous Structure

The porosity of a PSi layer is defined as the ratio between the volume of the void space to the total volume of the PSi layer. The effective refractive index of a PSi layer is related to its porosity by the Bruggeman effective medium model:

$$( 1 - P ) \frac{{ɛ}_{si} - {ɛ}_{PSi}}{{ɛ}_{si} + 2 {ɛ}_{PSi}} + P \frac{{ɛ}_{void} - {ɛ}_{PSi}}{{ɛ}_{void} + 2 {ɛ}_{PSi}} = 0 \qquad ( 1 )$$

where P is the porosity, εₛᵢ is the dielectric constant of silicon, ε_{PSi} is the effective dielectric constant of porous silicon and ε_{void} is the dielectric constant of the medium inside the pores (ε=n²). The Bruggeman effective medium model shows that the effective refractive index increases as the porosity decreases and as the dielectric constant of the medium inside the pores increases. In FIG. 9, the effective refractive index (n_{eff}) of PSi is plotted as a function of porosity. In sensing applications, ε_{void} increases due to the binding of targets to the internal surface of the PSi structure. Thus, the overall effective dielectric constant of the porous structure ε_{PSi} increases which causes a red shift in the optical reflectance spectrum of the structure. As shown in FIG. 9, for a given increase of ε_{void}, the effective refractive index change is larger for higher porosity layers.

The morphology of PSi is also strongly affected by the etching current density. The silicon dissolution process requires the presence of fluorine ions (F−) and holes (h+). As shown in FIG. 10, when the fluorine ions are delivered faster than the holes, the inter-pore regions of PSi are depleted of holes and further etching occurs only at the pore tips, where the holes are focused by the electric field. When the current density decreases, the number of holes at the pore tips drops, which leads to smaller pore sizes. Thus, the porosity can be precisely controlled by the etching current density. FIG. 11 shows the dependence of the porosity on current density for highly doped n-type (0.01 ohm-cm) silicon. Similar curves can be found on other types of substrates (PROPERTIES OF POROUS SILICON (Leigh Canham ed., 1997), which is hereby incorporated by reference in its entirety).

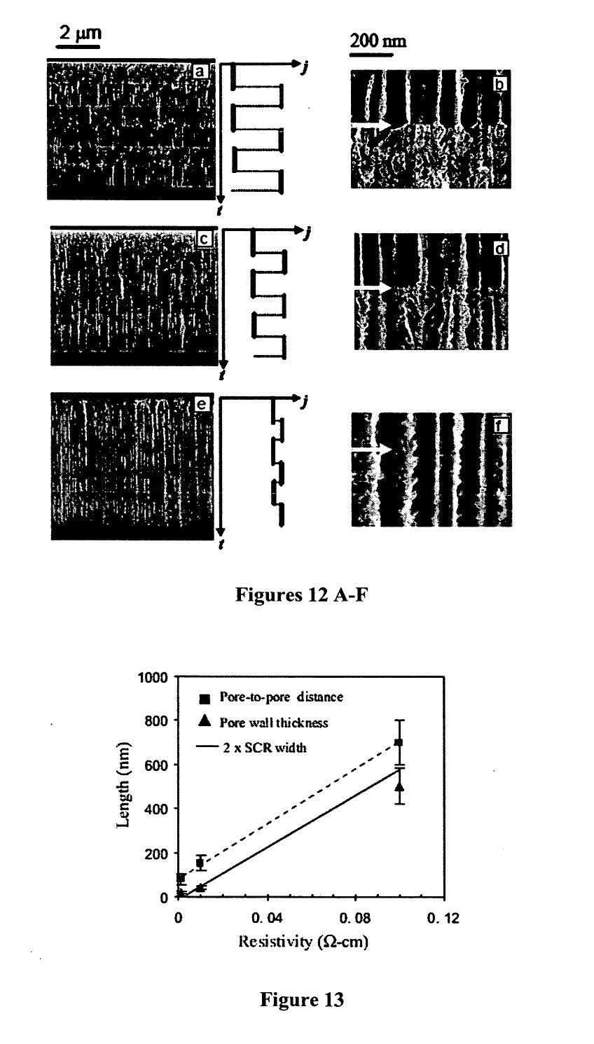

The refractive index of a PSi layer is related to its porosity by the Bruggeman effective medium approximation. Therefore, the refractive index profile of a porous silicon structure can be set by choosing the proper current density profile. This is because the already formed PSi layer is depleted of holes and further etching only occurs at the pore tips (Theiβ, “Optical Properties of Porous Silicon,” Surface Science Reports 29(3): 91-192 (1997), which is hereby incorporated by reference in its entirety). As shown in FIGS. 12A-F, by simply applying a periodic current density pulse train, a multilayer structure consisting of layers with distinct porosities is formed. The porosity of each layer is determined by the etching current density and their thickness is determined by the duration of the current pulse. If the current density changes sinusoidally, a rugate filter which has sinusoidal refractive index profile can be formed (Thonissen et al., “The Colourful World of Porous Silicon: From Interference Filters to Applications,” Solid State Phenom. 54:65-72 (1997), which is hereby incorporated by reference in its entirety). PSi thin films with engineered porosity gradients have also been used to achieve broadband antireflection coating on silicon wafers and solar cell substrates (Striemer & Fauchet, “Dynamic Etching of Silicon for Broadband Antireflection Applications,” Appl. Phys. Lett. 81 :2980-2982 (2002), which is hereby incorporated by reference in its entirety).

### Example 7

### Production of Microcavities with Tunable Pore Sizes (from Mesopores to Macropores)

Substrate Resistivity

The macropore-to-macropore distance in highly doped n-type silicon strongly depends on the substrate resistivity, as shown by the plot in FIG. 13. In n-type PSi, the pore-to-pore distance increases as the resistivity increases (Lehmann et al., “On the Morphology and the Electrochemical Formation Mechanism of Mesoporous Silicon,” Mater. Sci. Eng. B 69(70): 11-22 (2000), which is hereby incorporated by reference in its entirety). The pore-wall thickness measured from the top-view SEM image was approximately twice the space charge region (SCR) width, as expected for n-type porous silicon (Zhang, J. Electrochem. Soc. 138:3750 (1991); Searson et al., “Pore Morphology and the Mechanism of Pore Formation in n-Type Silicon,” J. Appl. Phys. 72:253 (1992), which are hereby incorporated by reference in their entirety). That the pore-to-pore distance in highly doped n-type silicon is much larger than the SCR width was also observed by others (Hejjo Al Rifai et al., “Dependence of Macropore Formation in n-Si on Potential, Temperature, and Doping,” J. Electrochem. Soc. 147(2):627-635 (2000), which is hereby incorporated by reference in its entirety). Since the pore morphology of the 0.01 Ω-cm wafer is the most advantageous for sensing large biomolecules, this pore morphology was chosen for further investigations of the biosensing platform. All samples discussed in this and the following Examples (unless otherwise stated) were etched from n-type silicon wafers with resistivity of 0.01 Ω-cm.

Etching Current Density

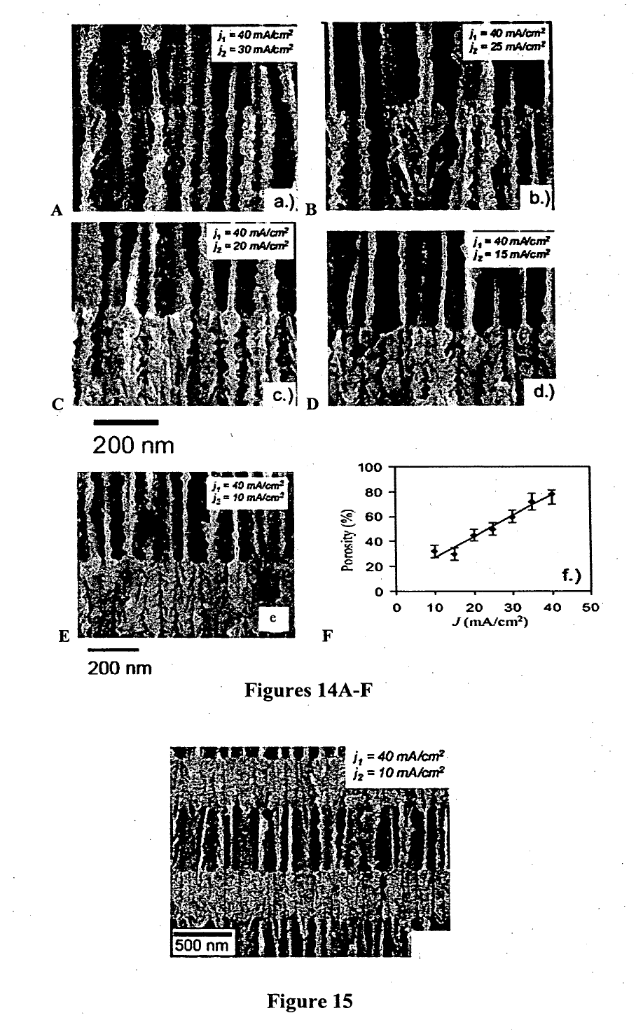

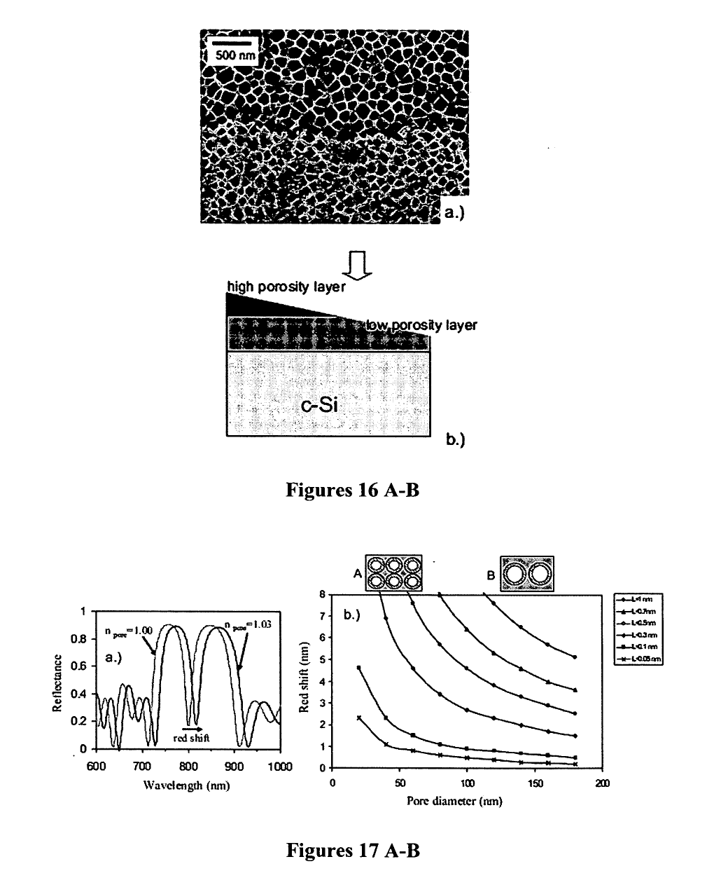

The dependence of the average pore diameter on the etching current density j was investigated. FIGS. 14A-E are SEM images showing the interface between two layers formed by two different current densities. All samples were first etched with current density j₁ (40 mA/cm²), which forms substantially straight and substantially smooth macropores with 120 nm diameter. The current density was then reduced to j₂. When j₂ decreased, the pore diameter decreased gradually from the macro-scale to the meso-scale, as shown in FIGS. 14A-E. Several trends were observed: (1) when the current density decreased, the pore wall roughness increased and the pore diameter decreased; (2) when the pore diameter decreased, branching side pores became visible; and (3) the layer morphology changed instantly as the current density changed, as indicated by the clear interface between the two different layers. Porosities ranging from 30% to 80% (measured gravimetrically using single layers) and pore diameters from approximately 20 to 120 nm were obtained by changing the current density from 10 mA/cm² to 40 mA/cm², as shown in FIG. 14F. This is the largest porosity range that can be obtained at room temperature using the given substrate and electrolyte solution. The ability to control the pore diameter and morphology provides control over the size of the biological targets that can infiltrate into the structure. Further ranges in porosity and pore diameters can be obtained by selection of the substrate (having different resistivity) and the etching medium (having different HF concentration). A multilayer structure with a very high contrast in porosity (defined as the percentage of void space in the material) is shown in FIG. 15. The continuity of the pore propagation through the layers, which is important for sensing applications, is maintained; this is due to the focusing of the electric field at the pore tips where silicon dissolution takes place (Lehmann & Rönnebeck, “The Physics of Macropore Formation in Low-doped n-Type Silicon,” J. Electrochem. Soc. 140:2836-2843 (1993), which is hereby incorporated by reference in its entirety). The plan-view SEM image shown in FIG. 16A shows the contrast in pore diameter and morphology for different porosities. The sample was polished with an angle, as illustrated in FIG. 16B.

### Example 8

### Principle and Sensitivity Modeling

Porosity and Refractive Index

The refractive index of a PSi layer can be related to its porosity by the Bruggeman effective medium approximation, described in Example 6 above. Therefore, the refractive-index profile of a PSi microcavity structure can be set by choosing the proper current-density profile.

Q-Factor

The Q-factor of a microcavity, which is defined as Q=λ/Δλ, where λ is the resonance center wavelength and Δλ is the full width at half maximum of the resonance dip, is used to evaluate how effectively light is confined within a photonic bandgap structure. The larger the Q, the more efficiently light is confined inside the cavity. In sensing applications where the shift of the spectrum is monitored, increasing the Q of the microcavity will increase the ability to resolve a small wavelength shift. Thus, the Q of the sensor should be as high as possible to increase the sensitivity. A higher contrast in porosity gives a higher value of the Q factor (Ouyang & Fauchet, “Biosensing Using Porous Silicon Photonic Bandgap Structures,” Proc. SPIE 6005 600508-1 (2005), which are hereby incorporated by reference in their entirety; Example 4, infra). Although a higher Q factor allows for the detection of smaller shifts (due to the sharper features in the spectrum), the higher contrast in porosity is produced by a higher contrast in pore opening, which may not be favorable for biosensing applications when easy infiltration throughout the entire multi-layer structure is required. For a given porosity contrast, the Q factor can also be increased by increasing the number of periods of the Bragg mirror. In practice, the number of periods cannot be increased arbitrarily for two reasons. First, uniform infiltration of the molecules becomes more difficult for thicker devices. Second, maintaining a constant HF concentration at the tip of very deep pores is difficult (Thonissen et al., “Analysis of the Depth Homogeneity of p-PS by Reflectance Measurements,” Thin Solid Films 297(l):92-96 (1997), which is hereby incorporated by reference in its entirety), which may lead to a change in the layers' properties.

Refractive Index and Optical Thickness

The resonance position of the microcavity is very sensitive to the optical thickness of each layer in the microcavity. A slight change of the refractive index inside the pores causes a red-shift of the spectrum. As shown in FIG. 17A, when the refractive index of the pores is increased by 3%, the resonance dip red-shifts by 18 nm for a microcavity with layers with porosities of 80 and 70% (Q=45). Due to the large interaction volume between the field inside the microcavity and the analyte, microcavities have a higher sensitivity than conventional ring resonators, where only the small evanescent tail of the field interacts with the analyte (Scheuer et al., “InGaAsP Annular Bragg Lasers: Theory, Applications, and Modal Properties,” IEEE J. Sel. Top. Quant. Electron. 11 (2):476-484 (2005), which is hereby incorporated by reference in its entirety). Thus, the sensitivity of a low-Q microcavity is comparable to that of a very-high-Q ring resonator.

Sensitivity and Pore Size

In biosensing applications, highly selective bioreceptors (e.g. DNA, antibody) are immobilized on the internal surface of the pores to capture specific molecules (targets). When the sensor is exposed to the targets, a monolayer of target species is coated on the surface of the sensor and causes a change in the refractive index. Thus, the refractive index change (Δn) of the sensor is determined by the size of the target species, the available binding surface area and the porosity of the sensor. In general, Δn increases as the size of the target and the binding surface area increase. The sensitivity of PSi microcavity optical sensors, therefore, is strongly related to the pore size. For a PSi layer with a given porosity, the internal surface area decreases as the pore size increases. The effective refractive-index change of a layer with larger pores is smaller, since the percentage of the pore volume occupied by the biological species is smaller. The red-shift of the spectra was simulated for microcavities with fixed porosities (80% for the high-porosity layer and 70% for the low-porosity layer) but different pore diameters (ranging from 20 to 180 nm). For a given thickness of the coating (with n=1.42, a typical value for biomolecules), the total amount of red-shift decreased as the pore size increased, as shown in FIG. 17B. It can be seen that, for a 1 nm thick coating layer, a microcavity with 40 nm pores produces a red shift of 23 nm, while a microcavity with 100 nm gives a red shift of only 10 nm. Thus, to optimize the sensitivity, the pore size should be as small as possible, while still allowing for easy infiltration of the biological material.

Detector Resolution

The sensitivity of the microcavity structure also depends on the detector resolution. Assuming a system capable of measuring a 1 nm shift, FIG. 17B shows that to detect a coating thickness of 0.05 nm the pore size needs to be smaller than 50 nm. If the pore size is 120 nm, the minimum coating-layer thickness that can be detected is 0.1 nm. From the measured shift and the pore size of the microcavity, one can estimate the thickness of the coating layer on the pore wall. Thus, the number of protein molecules captured inside the microcavity can be estimated if the size of the protein is known. From FIG. 17B the areal mass sensitivity in terms of gram/internal surface area can be estimated. A detection system able to resolve a shift of 0.1 nm was assumed. For a microcavity with 20 nm pores, the required minimum coating thickness to achieve a detectable signal is 0.002 nm, which is equivalent to ˜2 pg/mm². For a microcavity with 180 nm pores, the minimum coating thickness is 0.02 nm, which is equivalent to ˜20 pg/mm².

### Example 9

### Quantitative Analysis of the Sensitivity of Porous Silicon Optical Biosensors

The figure of merit describing the sensitivity of affinity sensors is Δλ/Δn, where Δλ is the wavelength shift resulting from the capture of biological or chemical molecules and Δn is the change of the ambient or pore refractive index. For a detection system capable of resolving a given wavelength shift, Δλ/Δn indicates the minimum detectable index change of the device. For a microcavity with layers of 80% and 70% porosity Δλ/Δnₚₒᵣₑ is ˜550 nm. For a system able to detect a wavelength shift of 0.1 nm, the minimum detectable refractive index change is 2×10⁻⁴. The sensitivity of PSi microcavities is related to several parameters such as thickness, resonance wavelength, pore size, porosity and the Q-factor.

Thickness

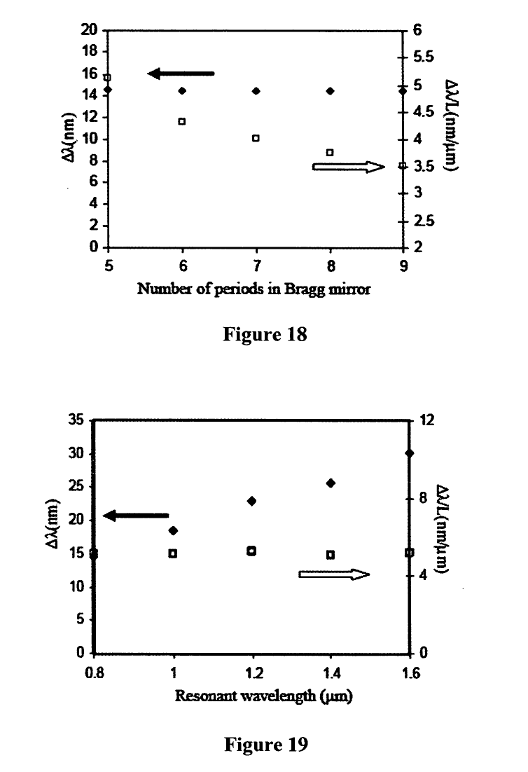

Due to the field confinement inside the 1-D PBG microcavity, the resonant dip is more sensitive to a change of the refractive index in the defect layer than in the Bragg mirrors. Layers farther away from the defect layer have less influence on the resonance wavelength (Ouyang et al., “Biosensing With One-dimensional Photonic Bandgap Structure,” Proc. SPIE 5511:71-80 (2004), which is hereby incorporated by reference in its entirety). Simulation results show that the red shift of the microcavity is independent of the number of periods in the Bragg mirror (see FIG. 18). However, as the number of periods increases, the total thickness of the device increases as well. If the amount of reagent is limited, a very thick sensor is not a good option because the total amount of reagent captured inside the microcavity is proportional to the thickness of the device. Therefore, the quantity Δλ/L was used to evaluate the sensitivity of sensors with different thicknesses (L). Δλ/L is equivalent to Δλ/g (wavelength shift per unit mass of reagent). As shown in FIG. 18, Δλ/L decreases as the number of periods in the Bragg mirror increases. Thus, in designing a sensor, the number of periods in the Bragg mirrors should be as low as possible provided that a reasonable Q-value of the microcavity is achieved.

Resonance Wavelength

The wavelength of the resonance is determined by the optical thickness of the defect layer and the Bragg mirrors. The red shift of the resonance as a function of the resonance wavelength is shown in FIG. 19. It can be seen from FIG. 19 that as the resonance wavelength moves to longer wavelengths, Δλ increases. Thus, if the amount of reagent is unlimited and easy infiltration of the reagent throughout the layers is possible, the resonance wavelength of the sensor should be designed to be as large as possible. FIG. 19 also shows that Δλ/L is independent of the resonance wavelength. Thus, if the amount of reagent captured inside the pores is fixed, microcavities with different resonance wavelengths have the same Δλ, or the same sensitivity.

Defect Layer Thickness

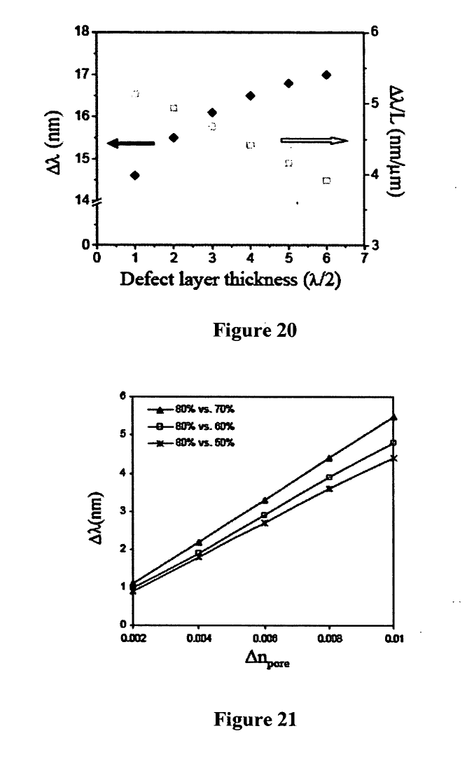

The number of resonances that exist in the stop band depends on the optical thickness of the defect layer. The red shift of the resonance dips is plotted in FIG. 20 as a function of the defect layer thickness. As the defect layer thickness increases the red shift of each resonance dip slowly increases and eventually saturates. However Δλ/L decreases as the thickness of the defect layer increases. Thus, for sensing applications, it is more efficient to design a microcavity with a defect layer of one half wavelength optical thickness or one wavelength optical thickness. As shown in FIG. 20, a very thick defect layer would not increase the sensitivity of the sensor very much. For a fixed total amount of reagent captured inside the pores, the thicker the active layer, the less sensitive the sensor.

Porosity

FIG. 21 shows how the red shift of the resonance depends on the changes in refractive index of the pores. In the simulation, the porosity of the defect layer and higher porosity layers in the Bragg mirrors is 80%. The lower porosity layer in the Bragg mirrors is varied from 50% to 70%. FIG. 21 also shows that for a given Δn, Δλ increases as the porosity of the low porosity layer increases, which results from an increase in the effective index change of the layers as indicated by FIG. 9. The sensitivity of the microcavity is Δλ/Δn˜450 nm. If the detection system is able to resolve a resonance shift of 0.2 nm, the minimum detectable index change Δn is ˜4×10⁻⁴.

Pore Size

Simulations show that for PSi affinity sensors with an average porosity of 75%, Δλ/Δn˜550 nm at a detection wavelength of 800 nm (Ouyang & Fauchet, “Biosensing Using Porous Silicon Photonic Bandgap Structures,” Proc. SPIE 6005 600508-1 (2005), which is hereby incorporated by reference in its entirety). When the refractive index inside the pores is increased homogenously, Δλ/Δn is the same for sensors with different pore sizes but the same porosity. However, in biosensing applications, the sensing species are attached only to the internal surfaces (pore walls) instead of completely filling the pores. In this case, the pore size becomes an important parameter, because for a PSi layer of a given porosity, the internal surface area (or the total number of available binding sites) decreases as the pore size increases. As described in this Example, the performance of PSi microcavity biosensors was quantitatively characterized by modeling the wavelength shift resulting from binding events in sensors with different pore sizes. Experiments were performed to demonstrate the influence of the pore size on the optical response and to verify the theoretical predictions.

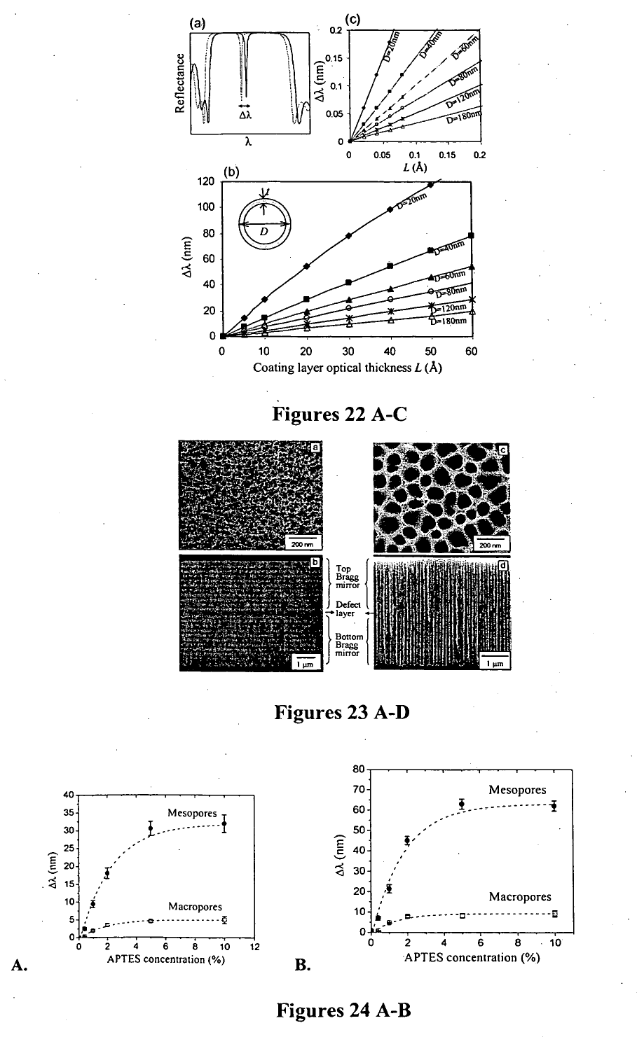

The reflectance spectrum of a PSi microcavity, which is characterized by a sharp resonance dip (Chan & Fauchet, “Tunable, Narrow, and Directional Luminescence From Porous Silicon Light Emitting Devices,” Appl. Phys. Lett. 75(2):274-276 (1999), which is hereby incorporated by reference in its entirety), was simulated by the transfer matrix method (HECHT & ZAJAC, OPTICS (1979), which is hereby incorporated by reference in its entirety). The effective refractive index of a PSi layer is defined by its porosity and the refractive indices of silicon and the pores (Theiβ, “Optical Properties of Porous Silicon,” Surface Science Reports 29(3): 91-192 (1997), which is hereby incorporated by reference in its entirety). Binding of biological molecules on the pore wall increases the effective refractive index of PSi and causes a red shift of the resonance dip, as shown in FIG. 22A. To quantitatively analyze Δnₚₒᵣₑ (the increase of refractive index of the pores due to the binding of a thin layer of molecules on the pore wall) a simplified effective medium approximation based on volume ratios is used:

$$Δ {n}_{pore} = {n}_{pore}^{after} - {n}_{pore}^{before} = 4 ( \frac{t}{D} - \frac{{t}^{2}}{{D}^{2}} ) {( {n}_{layer} - {n}_{pore}^{before} )}_{\approx }^{t << D} 4 \frac{t}{D} ( {n}_{layer} - {n}_{pore}^{before} ) \qquad ( 1 )$$

where D is the diameter of the pores, t is the thickness of the layer binding on the pore wall, n_{layer} is the refractive index of the binding layer, and nₚₒᵣₑ^{before} and nₚₒᵣₑ^{after} are the refractive index of the pore before and after binding (see FIG. 22B, inset). (The change in refractive index of the cylindrical pore after infiltration of a uniform layer coating is estimated by

$$Δ {n}_{pore} = [ \frac{{V}_{layer}}{{V}_{pore}} * {n}_{layer} + ( 1 - \frac{{V}_{layer}}{{V}_{pore}} ) * {n}_{pore}^{before} ] - {n}_{pore}^{before} , and \frac{{V}_{layer}}{{V}_{pore}} = \frac{{{π ( \frac{D}{2} )}^{2} - π \frac{D}{2} - t )}^{2}}{{π ( \frac{D}{2} )}^{2}} = 4 ( \frac{t}{D} - \frac{{t}^{2}}{{D}^{2}} ) \qquad ( 2 )$$

where V_{layer} is the volume of the coating layer and Vₚₒᵣₑ is the volume of the pore.) In the present Example, the pores are filled with air before binding, thus nₚₒᵣₑ^{before}=nₐᵢᵣ=1. Using this equation, the red shift of the spectra for microcavities with fixed porosities (75% for the high porosity layer and 65% for the low porosity layer) but different pore diameters ranging from 20 nm to 180 nm was simulated. The original resonance wavelength of the microcavity is 800 nm. The red shift of the resonance wavelength Δλ due to binding on the pore walls is plotted in FIG. 22B as a function of the optical thickness of the coating L=t·n_{layer} and the pore diameter D.

For a 30 Å-thick binding layer, a PSi microcavity with 20 nm pores produces a red shift of 78 nm, while a microcavity with 180 nm pores gives a red shift of only 10 mn. Thus, to optimize the sensitivity, the pore size should be as small as possible while still allowing for easy infiltration of the biological material. If the minimum detectable wavelength shift and minimum acceptable pore diameter are known, one can calculate the minimum detectable coating thickness, i.e., the sensitivity of the sensor. As shown in FIG. 22C, for a detection system capable of resolving a wavelength shift of 0.1 nm, the minimum detectable coating optical thickness is approximately 0.03 Å for a microcavity with 20 nm pores, whereas for a microcavity with 80 nm pores, it is approximately 0.13 Å.

To experimentally verify this simulation, two different types of PSi microcavities were used: mesoporous silicon microcavities with an average pore diameter of ˜20 nm, and macroporous silicon microcavities with an average pore diameter of ˜120 nm (Ouyang et al., “Macroporous Silicon Microcavities for Macromolecule Detection,” Adv. Funct. Mater. 15(11):1851-1859 (2005), which is hereby incorporated by reference in its entirety). FIGS. 23A-D show the morphology of the mesoporous and macroporous silicon microcavities. Both microcavities have layers with porosities of approximately 65% and 75%, corresponding to a refractive index of 1.60 and 1.33 in the infrared calculated by the Bruggeman effective medium approximation.

Aminopropyltriethoxysilane (APTES) and glutaraldehyde are common coupling agents that promote adhesion between oxidized silicon surfaces and organic molecules (HERMANSON, BIOCOJUGATE TECHNIQUES (1996), which is hereby incorporated by reference in its entirety). Furthermore, APTES and glutaraldehyde are small molecules that can form uniform thin layers on the internal surface of PSi, which makes them good model systems to quantitatively characterize the optical response of PSi biosensors. The microcavities were first thermally oxidized at 900° C. to create an oxide layer on the PSi internal surface to promote covalent attachment of APTES. After oxidation, the resonant wavelength of the microcavity is ˜800 nm. Then the microcavities were exposed to APTES solutions with different concentrations (APTES was diluted in a H₂O:methanol (1:1) mixture). Each sensor was exposed to the solutions for 20 minutes, then rinsed with DI water and methanol and dried with nitrogen. The silanized sensors were then baked in an oven at 100° C. for 10 minutes before the optical measurement was taken.

The reflectance spectra were taken using an Ocean Optics HR 2000 spectrometer with a reflection probe R200-7 (6 illumination fibers around 1 read fiber). As shown in FIG. 24A, the red shift of the resonance wavelength increases as the concentration of APTES increases for both mesoporous and macroporous silicon microcavities. The curves saturate when all the available binding sites are occupied i.e., when a monolayer of APTES coats the pore walls.

After silanization, the microcavities were exposed to a 2.5% glutaraldehyde solution in 20 mM Hepes buffer (pH=7.4) for 30 minutes, then rinsed with DI water and dried with nitrogen. Glutaraldehyde reacts with the amino groups on the silanized surface and coats the internal surface of the pores with another thin layer of molecules. It can be seen from FIG. 24B that after the binding of glutaraldehyde to the silanized surface, the maximum total red shift was twice that due to the binding of APTES alone shown in FIG. 24A. This confirms the specific binding between APTES and glutaraldehyde, and, in the saturation region, the formation of one uniform APTES monolayer inside the sensors. Because Δλ is linearly related to t as shown in FIG. 22, it also suggests that the thickness ratio of the APTES and glutaraldehyde layers is ˜1:1. For the same coating thickness inside the pores, the red shift was approximately 6 times larger with 20 nm mesopores than with 120 nm macropores, which is in a good agreement with equation (1).

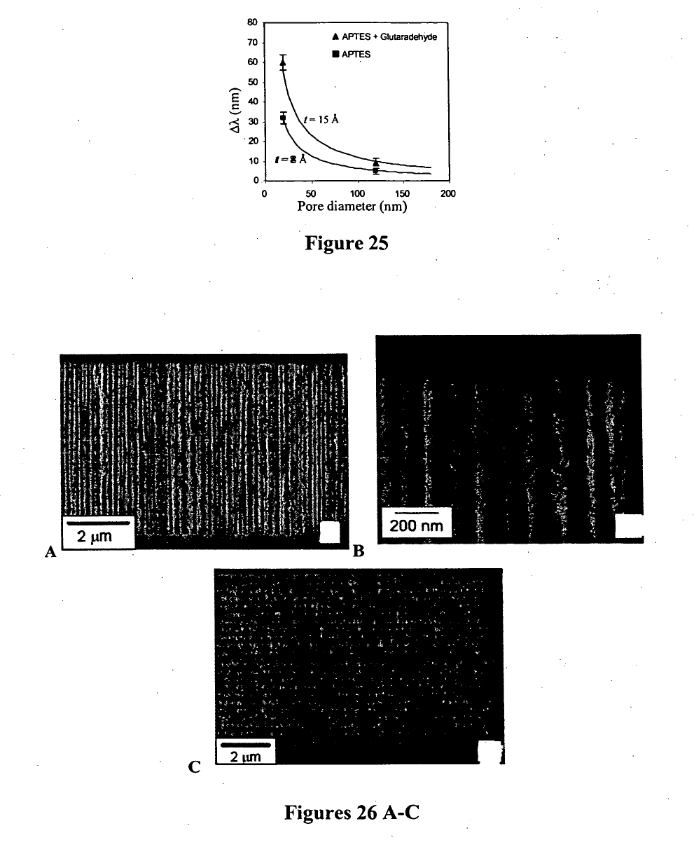

To compare the experimental results and the simulation, the optical thickness of APTES and glutaraldehyde was determined by variable angle spectroscopic ellipsometry on planar surfaces. Crystalline silicon wafers with a thin oxide layer were first treated with 5% APTES in H₂O and methanol (1:1) followed by 2.5% glutaraldehyde using the same procedure as described above. The refractive index of APTES and glutaraldehyde was measured to be 1.46±0.06. The physical thickness of one APTES monolayer was determined to be 8±1 Å, and the total thickness of the APTES+glutaraldehyde layer to be 15±1 Å. These results confirm the thickness ratio of APTES to glutaraldehyde to be ˜1:1. Using the refractive index and physical thickness of APTES and glutaraldehyde measured by ellipsometry, the red shift of the spectra was simulated using the effective media approximation described above. The simulated red shift as a function of the pore size is plotted as the solid curves in FIG. 25. The top curve corresponds to a coating layer with t=15 Å, and the bottom curve corresponds to a coating layer with t=8 Å. As shown in FIG. 25, the experimental results obtained using mesoporous and macroporous microcavities were in excellent agreement with the simulations.

In conclusion, PSi optical biosensors with different pore sizes were quantitatively characterized using a simplified effective medium approximation. The wavelength shifts measured with microcavities after the binding of thin layers of molecules with different thicknesses were in excellent agreement with simulations. Simulations show that binding a very small amount of biological targets, equivalent to a continuous layer less than 0.1 Å thick, is possible with a high Q (>2000) microcavity and a detection system capable of resolving a wavelength shift of 0.1 nm.

### Example 10

### Controlling the Optical Thickness of the Macroporous Microcavity Layers

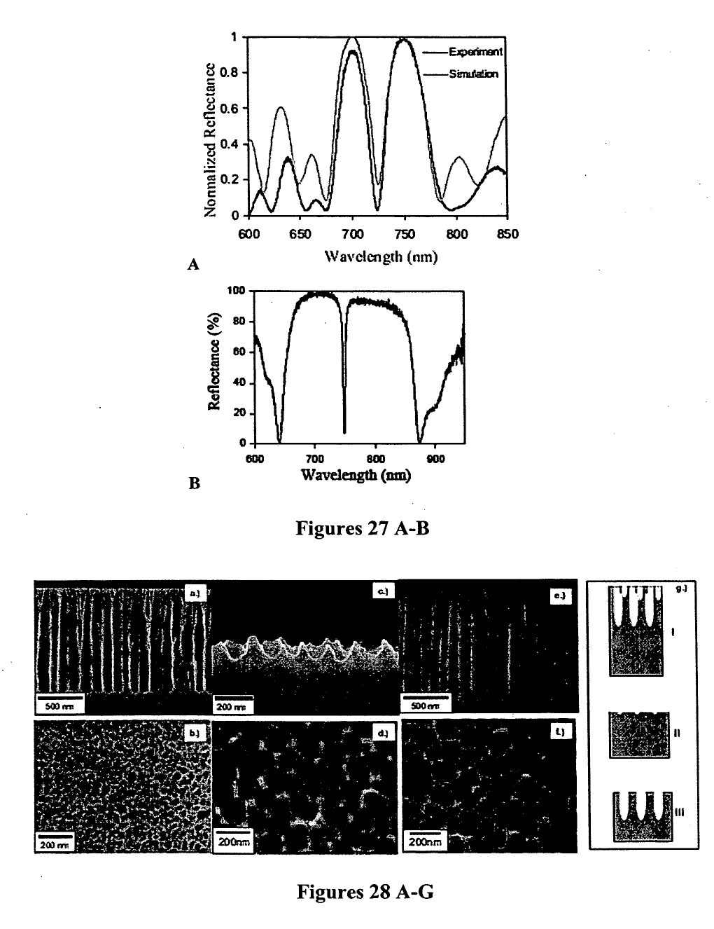

Once the porosity and etch rate for each current density are calibrated, it is possible to form microcavities in which the optical thickness of each layer is carefully controlled. FIGS. 26AC and FIGS. 27A-B respectively show the cross-sectional SEM images and reflectance spectra of two microcavities with different morphologies. FIGS. 26A-B show cross-sectional SEM images of a macroporous microcavity. This one-dimensional photonic band gap structure has a defect (symmetry-breaking) layer sandwiched between two Bragg mirrors. Each Bragg mirror is a periodic stack of two quarter-wavelength optical thickness layers of different porosities. Exemplary etching parameters are shown in Table 2. Preferably, a few seconds of etching stops (in which the current is set to zero) is applied between each current pulse in order to allow the HF acid concentration to equilibrate throughout the porous matrix. A 5-second etch stop was applied in this Example.

TABLE 2
Etching parameters for macroporous microcavity

| Current | | | | |
|---|---|---|---|---|
| density | Etching | | Etching | |
| (mA/cm²) | time (s) | | period | Function |
| 40 | 30 | | 1 | Sacrificial layer* |
| 250 | 1.5 | | 2 | Electropolish away |
| | | | | sacrificial layer* |
| 40 | 7 | | | |
| | | {close oversize brace} | 10 | Bragg Mirror |
| 30 | 5 | | | |
| 40 | 14 | | 1 | Defect layer |
| 33 | 5 | | | |
| | | {close oversize brace} | 12 | Bragg Mirror** |
| 40 | 7 | | | |

*See Example 11.
**The optical quality of the microcavity was improved by using more etching periods and a higher current density for the lower porosity layer in this Bragg mirror.

A very low porosity contrast was chosen (˜80% versus ˜75%) to keep the large opening of the overall structure for macromolecule sensing. The microcavity was fabricated by using alternating current densities between 40 and 32 mA cm⁻². Before the formation of the microcavity, the “prestructuring” step, as described in Example 11, was carried out to ensure the opening at the top of the microcavity. As shown in FIG. 26B, the pores on the top of the microcavity were completely opened. The measured microcavity reflectance spectrum (black line) and a matching simulation curve (gray line) are shown in FIG. 27A. In the simulation, porosities of 80 and 76% were used. The pore opening in the macroporous microcavities of the present invention is larger than in any mesoporous device reported to date (Chan et al., “Identification of Gram Negative Bacteria Using Nanoscale Silicon Microcavities,” J. Am. Chem. Soc. 123(47):11797-11798 (2001); Schmedake et al., Appl. Phys. Lett. 76:18 (2000), each of which is hereby incorporated by reference in its entirety). Easy infiltration of the biological materials is expected and sensing large molecules becomes possible with the microcavities of the present invention. For small molecule-sensing applications, lower current densities can be used to create smaller macropores inside the microcavity.

FIG. 26C shows a mesoporous silicon microcavity with pore sizes between 10 nm to 50 m. The layers have porosities of 50% and 75%. The reflectance spectrum of the microcavity is shown in FIG. 27B.

### Example 11

### Electropolishing Process for Creating the Defects for Opening the Pores

Because of the way in which pore initiation occurs, a nanomesoporous layer is first produced before well-developed, stable macropores are formed (Lehmann & Föll, “Formation Mechanism and Properties of Electrochemically Etched Trenches in n-Type Silicon,” J. Electrochem. Soc. 137:653-659 (1990), which is hereby incorporated by reference in its entirety). This initial porous layer (or “nucleation layer”) has very small pore openings, as shown in FIGS. 28A and 28B, which could prevent the infiltration of relatively large objects (i.e., those larger than the openings) into the deeper, wider pores, and render the device useless. Small pores are formed because any random defect on the surface can trigger a pore to grow. However, as the pores continue to propagate and reach the equilibrium stage, lots of small pores stop growing because the number of pores and the pore density are determined by the depletion width or the doping level of the wafer (Lehmann & Rönnebeck, “The Physics of Macropore Formation in Low-doped p-Type Silicon,” J. Electrochem. Soc. 146(8):2968-2975 (1999); Tinsley-Bown et al., “Tuning the Pore Size and Surface Chemistry of Porous Silicon for Immunoassays,” Phys. Stat. Sol. (a) 182(1):547-553 (2000); each of which is hereby incorporated by reference in its entirety). To eliminate this nucleation layer, the wafer can be prestructured by seeding the pore formation via the creation of defects on the surface. This prestructuring can be triggered by KOH etching preceded by lithography (Lehmann & Föll, “Formation Mechanism and Properties of Electrochemically Etched Trenches in n-Type Silicon,” J. Electrochem. Soc. 137:653-659 (1990), which is hereby incorporated by reference in its entirety). However, this traditional method requires additional steps. Instead, a novel, convenient way to “prestructure” the wafer (i.e. eliminate the nucleation layer and create defects on the surface that serve as the seeding for pore formation) was developed.

A sacrificial layer (˜1 μm thick) was first etched. A higher current density pulse was then applied to electropolish away the sacrificial layer. A similar procedure has been employed to obtain freestanding PSi thin films (von Behren et al., “Preparation and Characterization of Ultrathin Porous Silicon Films,” Appl. Phys. Lett. 66:1662 (1995), which is hereby incorporated by reference in its entirety). By adjusting the electropolishing current density and the time (two pulses of 250 mA/cm² for 1.5 seconds), the top layer was successfully removed while at the same time a surface with defects was created, as shown in FIGS. 28C and 28D. These defects are from the pore tips in the bottom of the sacrificial layer and have the same center-to-center distance as the pores that have already reached the equilibrium stage.

After the electropolishing step, a normal etching process can be carried out. In the further etching process, the pores originate from the defects created on the “new” surface formed during the electropolishing step; no nucleation layer is formed during this etching step. FIGS. 28E and 28F demonstrate that the pore openings on the top of a microcavity layer etched after the electropolishing process are the same size as the pore openings at the bottom of the layer. FIG. 28G depicts this process.

It was discovered that the optimum current density for the electropolishing process is independent of the HF acid concentration.

### Example 12

### Etching with Additional Oxidizer

It is known that an oxidizer (for example, chromium trioxide (CrO₃)), can be added into the HF acid based solution to help the dissolution of silicon (Christophersen et al., “Macropore Formation on Highly Doped n-Type Silicon,” Phys. Stat. Sol. (a) 182(1):45 (2000); Safi et al., “Etching of n-Type Silicon in (HF+Oxidant) Solutions: In Situ Characterisation of Surface Chemistry,” Electrochim. Acta. 47(16):2573-2581 (2002); each of which is hereby incorporated by reference in its entirety). It was discovered that if CrO₃ is added to the HF acid solution, the electrochemically-etched porous silicon will be further chemically dissolved by CrO₃, thus the pore size can be further enlarged.

A pore morphology similar to that described in Examples 1, 4, 6, and 7 can be achieved with a lower current density by adding 300 mg of CrO₃ in the 6% HF acid solution (200 ml H₂O+25 ml HF+1 ml surfactant). 30% to 80% porosity can be obtained by changing the current density from 10 mA/cm² to 25 mA/cm². The effect of adding different total amounts of CrO₃ (from 50 mg to 300 mg) in the 6% HF acid solution was investigated. Generally, the current density required to achieve the macropores decreased as the total amount of CrO₃ increased, although when more than 350 mg of CrO₃ was added into the solution, it was very hard to obtain a stable PSi structure because all the electrochemically-formed PSi was chemically dissolved by the solution.

There was also a slow chemical dissolution process taking place on the PSi-electrolyte interface due to the presence of CrO₃ in the electrolyte. Since the speed of the chemical dissolution on the top of the already-formed PSi layer is slower than the pore growth rate of the electrochemical process, a top layer can first be formed before etching the microcavity in order to avoid dissolution of the top Bragg mirror. The thickness of the top layer can be designed such that it will be dissolved when the bottom Bragg mirror is formed. Details of the etching parameters are shown in Table 3.

TABLE 3
Etching parameters for the microcavity biosensor
with solution consisting of 300 mg CrO₃, 200 ml H₂O,
25 ml HF and 1 ml surfactant.

| Current | | | | |
|---|---|---|---|---|
| density | Etching | | Etching | |
| (mA/cm²) | time (s) | | period | Function |
| 15 | 200 | | 1 | Top layer |
| 25 | 9 | | | |
| | | {close oversize brace} | 6 | Bragg Mirror |
| 18 | 8 | | | |
| 25 | 18 | | 1 | Defect layer |
| 25 | 9 | | | |
| | | {close oversize brace} | 6 | Bragg Mirror |
| 18 | 8 | | | |

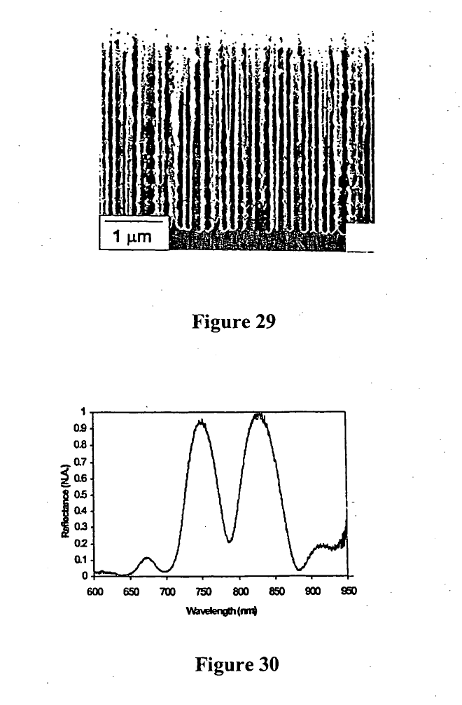

A 2 second regeneration step, in which the current is set to zero, is applied between each current pulse. A cross sectional SEM image of the microcavity and its reflectance spectrum is shown in FIGS. 29 (SEM) and 30 (reflectance spectrum).

### Example 13

### Infiltration Properties of the Macroporous Microcavities

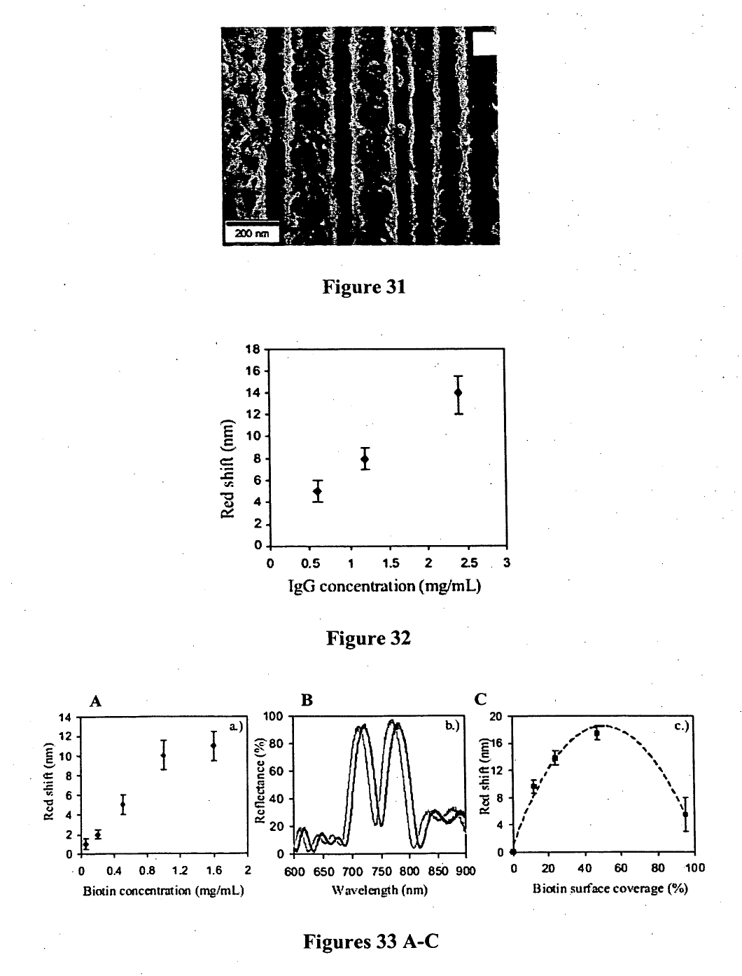

Easy infiltration of large objects into the macroporous microcavity is expected due its large pore size, as shown in FIG. 26B (approximately 120 nm for the high-porosity layer and 100 nm for the low-porosity layer). To test the infiltration property of the macroporous microcavity, latex microspheres with a diameter from 10 nm to 60 nm were infiltrated into the structure. FIG. 31 is a cross-sectional SEM image of the macroporous microcavity with latex spheres inside the pores. It shows that the opening of the pores is large enough to allow infiltration of objects with 60 nm diameter, which is larger than most proteins.

### Example 14

### Accessibility of the Microcavity to Large Biomolecules

The accessibility of the macroporous microcavity to large biological molecules was investigated using rabbit IgG (150 kDa; 1 Da=1 g mol⁻¹) using microcavities fabricated as described in Example 4. From the X-ray crystal structure, the longest dimension of IgG is approximately 17 nm (Saphire et al., “Crystal Structure of a Neutralizing Human IGG Against HIV-1: A Template for Vaccine Design,” Science 293(5532):1155-1159 (2001), which is hereby incorporated by reference in its entirety). It is very difficult to infiltrate IgG into a mesoporous (≦20 nm) microcavity. To functionalize the sensor for the capture of IgG, the microcavity sensor was first thermally oxidized at 900° C. for three minutes to form a silica-like internal surface. The spectrum blue-shifted by approximately 100 nm after the oxidation, as part of the Si was converted into SiO₂, which has a lower refractive index. Next, the internal surface of the microcavity was derivatized via 3-aminopropyltriethoxysilane, followed by glutaraldehyde. The stability of the sensor after the surface derivatization was tested in 20 mM HEPES (N-[2-hydroxyethyl]piperazine-N′-[2-ethanesulfonic acid]) buffer solution (pH 7.3). No shift of the spectrum was detected after the sensor was continually exposed to the buffer for 4 days. After exposure to 50 μl IgG solution (concentration varied from 0.6 to 2.4 mg ml⁻¹), a red-shift of the spectrum was observed. The red-shift of the spectrum as a function of the IgG concentration is plotted in FIG. 32.

### Example 15

### Biotin-Streptavidin Assay

To characterize the performance of the biosensing platform of the present invention, the streptavidin-biotin couple was used as a model system (Ouyang et al., “Label-free Optical Sensing of Proteins with Porous Silicon Microcavities,” CLEO 2005 CThP4 (2005); Ouyang & Fauchet, “Biosensing Using Porous Silicon Photonic Bandgap Structures,” Proc. SPIE 6005 600508-1 (2005), which are hereby incorporated by reference in their entirety). Streptavidin and biotin have a very high binding affinity for each other (dissociation constant, κ_{d}˜10⁻¹⁵ M) (Green, “Avidin,” Adv. Protein Chem. 29:85-133 (1975), which is hereby incorporated by reference in its entirety). While biotin is a small molecule, streptavidin is relatively large (67 κDa), making its infiltration into mesopores (≦20 nm) difficult but much easier into macropores. Furthermore, each streptavidin tetramer has four equivalent sites for biotin (two on each side of the complex), which makes it a useful molecular linker. To create a biotin-functionalized sensor for the capture of streptavidin, the microcavity sensor was first thermally oxidized at 900 degrees for 3 minutes. A silica-like internal surface formed after oxidation. A spectral blue shift of approximately 100 nm was observed after oxidation because part of the PSi is converted into SiO₂, which has a lower refractive index. The sensor was fabricated as described in Example 4. In particular, the sensor was silanized with 2% aminopropyltrimethoxysilane to create amino groups on the internal surface. A 4-5 nm red-shift was detected after silanization, since matter was added to the pores. Next, the probe molecules, Sulfo-NHS-LC-LC biotin (sulfosuccinimidyl-6-(biotinamido)-6-hexanamido hexanoate) in 50 mM PBS (phosphate buffered saline) buffer (pH 7.5), were immobilized inside the pores. The N-hydroxylsuccinimide (NHS)-activated biotin reacts efficiently with the primary amino groups to form stable amide bonds. The red-shift of the spectrum after exposure to biotin as a function of biotin concentration is shown in FIG. 33A. No shift was observed with buffer that did not contain biotin. By using the simulation discussed in Examples 8 and 9, the biotin surface coverage, which is linearly related to the red-shift in FIG. 33A, can be estimated (using a simple model assuming that the pores are perfect cylinders with an average diameter of 120 nm and the layer of biotin on the pore wall is ˜2 nm thick). A 10 nm red-shift corresponds to a nearly complete (95%) biotin surface coverage.

To study how the biotin surface coverage affects the binding of streptavidin, sensors derivatized with different biotin concentrations were exposed to the same amount of the target: 50 μL of streptavidin with a concentration of 1 mg/ml in 20 mM potassium phosphate buffer (pH 6.5). Comparing the reflectance spectra of the sensor before and after exposure to streptavidin, a red-shift was detected, which was attributed to the specific binding of streptavidin to the biotin-derivatized macroporous microcavity (Ouyang & Fauchet, “Biosensing Using Porous Silicon Photonic Bandgap Structures,” Proc. SPIE 6005 600508-1 (2005), which is hereby incorporated by reference in its entirety), as shown in FIG. 33B. For the control samples that were silanized but did not contain biotin, no shift was detected after exposure to streptavidin, which indicates that there is no or very little non-specific absorption of streptavidin inside the microcavity. The red-shift caused by streptavidin binding to biotin is a function of the biotin surface coverage. FIG. 33C shows that there is an optimum biotin surface coverage (˜50%) that maximizes the capture of streptavidin, hence the red-shift. This is in good agreement with the observations of others using different sensing techniques (Jung et al., “Binding and Dissociation Kinetics of Wild-type and Mutant Streptavidins on Mixed Biotin-containing Alkylthiolate Monolayers,” Langmuir 16(24):9421-9432 (2000); Pérez-Luna et al., “Molecular Recognition between Genetically Engineered Streptavidin and Surface-Bound Biotin,” J. Am. Chem. Soc. 121(27):6469-6478 (1999), which are hereby incorporated by reference in their entirety). The spacing between each neighboring biotin needs to be large enough so that biotin can reach the pocket-like binding sites of the streptavidin. The decrease in the red-shift in FIG. 33C is due to the fact that when the biotin surface density becomes very high and each biotin is closely surrounded by its neighbors, it cannot protrude deep enough into the binding site of streptavidin, thus decreasing the probability of capturing streptavidin.

The sensitivity of the macroporous microcavity for streptavidin detection currently is 50 μL of a 1-2 μM solution, which is equivalent to 0.3 ng nm⁻² in the porous internal surface (˜20000 mm²). By using the simulation discussed in Examples 8 and 9, the total amount of protein bound to the pores was estimated to be approximately 10-50 pg mm⁻², which is equivalent to 1-2% of a protein monolayer. The simulation suggests that less than 10% of the protein molecules exposed to the sensor was captured inside the microcavity. This can be explained by the fact that the entire volume of the PSi sensor (˜1 μL) is a small fraction of the solution (50 μL) applied to the sensor. The concentration limit of detection may be improved by using a flow-through system that would increase the likelihood that all the proteins access the PSi matrix.

In conclusion, a new type of well-defined macroporous silicon on highly doped n-type silicon has been fabricated, and its use in macromolecule-biosensing applications has been demonstrated. A wide range of morphologies, from 120 nm smooth macropores to spongy 20 nm mesopores, can be achieved on the same substrate using the same electrolyte, by precisely controlling the etching-current density. An electropolishing process was developed to create corrugations (i.e. defects) that can help to ensure large pore openings on the surface. A macroporous microcavity capable of serving as an optical, label-free biosensing platform was fabricated based on the new morphology. The infiltration properties and biosensing ability of the microcavity was demonstrated with rabbit IgG (150 kDa) and the biotin-streptavidin system. The results described in Examples 1 and 4 show that this stable and uniform macroporous structure allows easy infiltration of large molecules, and opens the door for large-molecule sensing applications with PSi.

### Example 16

### Detection of IgG

IgG is the most common type of antibody synthesized in response to a foreign substance (antigen). The antibody has a specific molecular structure capable of recognizing a complementary molecular structure on the antigen which might be some proteins, polysaccharides, and nucleic acids. From the X-ray crystal structure, the longest dimension of IgG is approximately 17 nm, and this IgG can be infiltrated into macroporous silicon with pore diameters of 120 nm.

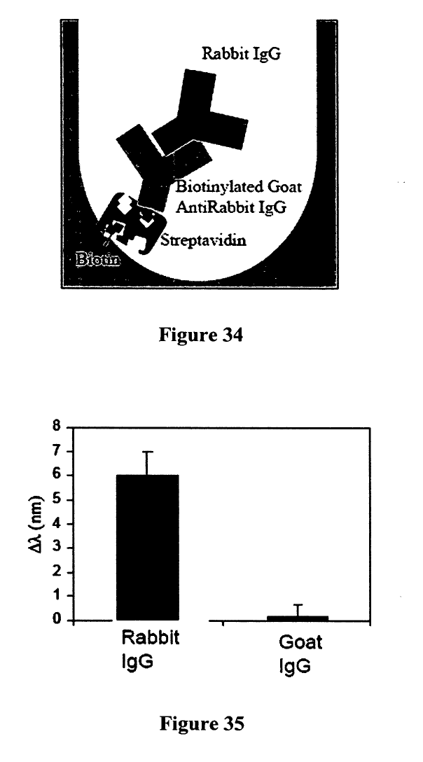

The detection of Rabbit IgG (150 kDa) was investigated through multiple layers of biomolecular interactions in a macroporous silicon 1-D PBG microcavity sensor. As illustrated in FIG. 34, the silanized sensor was first derivatized with biotin, which can selectively capture streptavidin as described in Example 15. The immobilized streptavidin can be used as a linker because of its free binding sites. Exposure of biotinylated Goat Anti-Rabbit IgG to the sensor resulted in its attachment to the surface through the binding between biotin and streptavidin. Goat Anti-Rabbit IgG was used as the probe molecule in the sensor to selectively capture Rabbit IgG. A red shift of the spectrum was detected when each layer of molecules was added to the sensor. As shown in FIG. 35, when the sensor was exposed to 50 μl of a solution containing Rabbit IgG at a 1 mg/ml concentration, a 6 nm red shift was detected. When the sensor was exposed to 50 μl Goat IgG (1 mg/ml), which does not bind to the Goat Anti-Rabbit IgG, the red shift was extremely small (<0.5 nm). This Example demonstrates that the sensor can selectively detect Rabbit IgG.

### Example 17

### Label-Free Quantitative Detection of Protein Using Macroporous Silicon Photonic Bandgap Biosensors

To further explore the capability of macroporous 1-D PBG sensor for protein detection the selective and quantitative label-free detection of pathogenic Escherichia coli (E. coli) was investigated. Initial studies were done employing the recombinant proteins, Intimin and Tir (Translocated Intimin Receptor), which are two proteins expressed by the enteropathogenic (EPEC) and the enterohemerogaic (EHEC) E. coli strains via the Type III secretory pathway. Both proteins are essential components of this organism's pathogenicity (Zaharik et al., “Delivery of Dangerous Goods: Type III Secretion in Enteric Pathogens,” Int. J. Med. Microb. 291(8):593-603 (2002), which is hereby incorporated by reference in its entirety). The dissociation constant of Tir-Intimin is about 0.3 μM (Homer et al., “A Proteomic Biosensor For Enteropathogenic E. coli,” Biosens. Bioelectron. 21(8):1659-1663 (2006), which is hereby incorporated herein by reference in its entirety), which is considerably lower than the biotin-streptavidin model system described in Example 15. This difference in the dissociation constant introduces the effect of equilibrium on detection sensitivity (Ouyang et al., “Macroporous Silicon Microcavities for Macromolecule Detection,” Adv. Funct. Mater. 15(11):1851-1859 (2005), which is hereby incorporated by reference in its entirety). The extracellular portion of the Tir intimin binding domain (Tir-IBD) was immobilized in the macroporous silicon microcavity as the probe molecules (the bioreceptor). Tir-functionalized sensors were found to selectively capture the target molecule, the extracellular domain of Intimin (intimin-ECD). This Example describes the investigation of the utility of the sensor for quantitative analysis, the dependence of the sensor performance on the probe molecule concentration, and the ability of the sensor to selectively and quantitatively detect the Intimin in the supernatant of an EHEC cell lysate.

Porous Silicon Microcavity Preparation

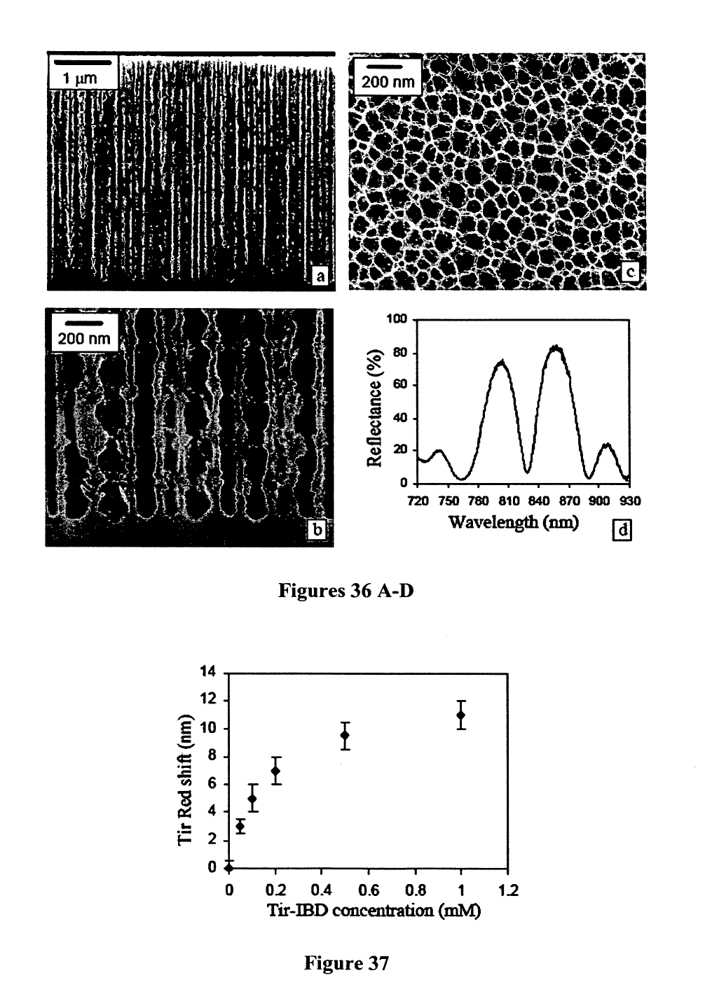

Macroporous silicon 1-D PBG microcavities were electrochemically synthesized from n-type silicon wafer with 0.01 ohm-cm resistivity (SEH Inc.) using an electrolyte solution containing 5.5% hydrofluoric acid (HF), 94% H₂O and 0.5% surfactant (Wako NCW1001). The etching area of each sensor was approximately 150 mm². During the microcavity formation, the etching current density, j, was alternated between 40 mA/cm² and 34 mA/cm² to form multilayer microcavities consisting of layers of distinct porosity. A very low porosity contrast was chosen (˜80% vs. ˜70%) to keep the pores as large as possible throughout the entire structure. The microcavities had two 8-period Bragg mirrors, and a defect layer of half wavelength optical thickness. The cross sectional and top view scanning electron micrographs (SEM) of a microcavity sensor are shown in FIGS. 36A-C. The average pore diameter was approximately 120 nm and the total thickness of the sensor was ˜5 microns. The optical reflectance spectra, shown in FIG. 36D, of the porous silicon microcavities were taken using an Ocean Optics HR 2000 spectrometer with a reflection probe R200-7 and an Ocean Optics LS-1 tungsten halogen light source. The illumination spot size was approximately 1 mm².

After anodization, the microcavities were thermally oxidized at 900° C. for 3 minutes to form a silica-like internal surface. The spectrum blue-shifted by approximately 100 nm after oxidation, as part of the silicon was converted into SiO₂, which has a lower refractive index.

Protein Preparation

Proteins were purified and quantified as described in Homer et al., “A Proteomic Biosensor For Enteropathogenic E. coli,” Biosens. Bioelectron. 21(8):1659-1663 (2006), which is hereby incorporated herein by reference in its entirety. Independent overnight cultures of transformed E. coli BL21 expressing 6×His-Tir-IBD (˜7 kDa) and 6×His-Intimin-ECD (32 kDa) were grown at 37° C. to OD 0.6 and induced with 1 mM IPTG overnight at room temperature. Tir-IBD and Intimin-ECD were purified using Amersham Biosciences-HiTrap Chelating columns and dialyzed in Hepes buffer (20 mM HEPES, 150 mM NaCl, pH 7.5). The concentrations of the purified proteins were measured by OD at 280 nm using molar extinction coefficients (ε^{Tir}=705.26, ε^{Intimin}=36960).

Sensor Functionalization

The probe molecule (Tir-IBD) was immobilized on the porous silicon matrix using standard aminopropyltriethoxysilane (APTES) and glutaraldehyde coupling chemistry. 50 μl of 2% 3-aminopropyltriethoxysilane (Gelest Inc.) in 48% methanol and 50% H₂O was applied to each sensor for 20 minutes. The sensors were then rinsed with water and baked in an oven at 100° C. for 10 minutes. Following the silane treatment, 50 μl of 2.5% glutaraldehyde (Sigma) solution in 20 mM Hepes buffer (pH 7.3) was applied to each sensor for 30 minutes. Sensors were rinsed with Hepes buffer and dried in a stream of nitrogen. Next, a series of sensors were fabricated by applying 50 μl of Tir-IBD with concentrations ranging between 0 and 1 mM. The sensors were exposed to the Tir-IBD solution for 1 hour. To prevent non-specific binding of Intimin-ECD to un-reacted glutaraldehyde sites, each sensor was exposed to 50 μl of 1M glycine methyl ester (pH 5) for 1 hour. After blocking, each sensor was rinsed and soaked in Hepes buffer for 20 minutes and dried with nitrogen flow before exposure to the target solution.

Target Incubation, Protein Supernatant and Controls

For target incubation, 50 μl of the Intimin-ECD solution (5 μM to 60 μM) was applied on the sensor for 1 hour, and then rinsed/soaked with Hepes buffer for 1˜2 hours and dried with nitrogen flow before the optical measurement was taken. To determine the selectivity of the sensor to Intimin-ECD, independent overnight cultures of an Intimin-ECD-expressing E. coli strain (“INT-strain”), and strain JM109 (Stratagene), which does not express Intimin-ECD, were grown up, centrifuged, lysed and then resuspended in Hepes buffer (pH=7.5). The supernatant solution was filtered through a 0.45 μm filter before exposure to the sensor. The existence and absence of Intimin-ECD in the protein supernatants from INT-strain and strain JM109 were verified using 2-D gel electrophoresis. Using the Bio-Rad Protein Assay, the total concentration of protein in the BL21 cell lysate was determined to be 2.4 mg/ml for the INT-strain and 2.2 mg/ml for the JM109 line.

Results and Discussions

A PSi 1-D BPG microcavity contains a defect (symmetry breaking) layer sandwiched between two Bragg mirrors. The optical spectrum of a microcavity is characterized by narrow resonances that are very sensitive to the effective optical thickness of each layer. When the sensor is exposed to the target, binding of target species inside the pores increases the effective refractive index of the pores and causes a red shift of the resonance position. The total amount of red shift is linearly related to the amount of analyte captured by the sensor. Details of the sensor sensing principle, design and optimization is described in the preceding Examples. Simulations show that for a microcavity with layers of 80% and 70% porosity, the sensor has a sensitivity (Δλ/Δn) of ˜500 nm, where Δλ is the shift of the resonance and Δn is the change of the effective refractive index of the pores. For a detection system able to resolve a shift of 0.5 nm, the minimum An that can be detected is 2×10⁻³, which is equivalent to an internal surface areal mass of ˜50 pg/mm² for sensors with 100 nm pore size.

A series of sensors derivatized with APTES and glutaraldehyde were exposed to Tir-IBD solutions with concentrations from 0 mM to 1 mM. As shown in FIG. 37, the red shift of the spectrum increased as the concentration of Tir-IBD increased. Since the red shift of the spectrum is approximately linearly related to the amount of protein captured in the microcavity, the results indicate that the total amount of protein immobilized in the sensor increased as the concentration of the protein increased. Thus, different probe molecule surface concentrations can be prepared. At high Tir-IBD exposure, a saturation of the red shift occurs, as is expected if all available binding sites of the sensor are filled and multilayer adsorption does not occur.

Based on the model for the quantitative analysis of the sensor sensitivity, a 0.5 nm red shift of the microcavity corresponds to ˜50 pg/mm² of protein captured inside the pores. Thus, in this case, a 12-nm red-shift corresponds to ˜1.2 ng/mm² of Tir. Assuming the total internal surface area of the sensor is 15000 mm², the total mass of Tir captured by the sensor is ˜18 μg or 2.6 nmol.

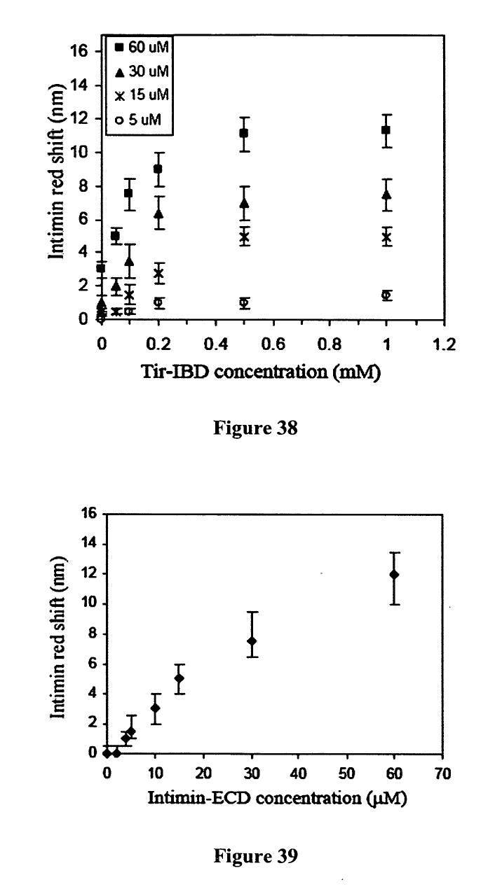

It is known that the kinetics of proteins binding to surface-tethered-receptors may be impacted by steric effects, which are particularly exacerbated in the case of multivalent proteins. Studies have shown that the performance of solid phase sensors may depend on probe molecule surface density (Jung et al., “Binding and Dissociation Kinetics of Wild-type and Mutant Streptavidins on Mixed Biotin-containing Alkylthiolate Monolayers,” Langmuir 16(24):9421-9432 (2000), which is hereby incorporated by reference in its entirety). To investigate the importance of this effect on the binding of Intimin-ECD, the magnitude of the sensor shift as a function of the Tir-IBD surface concentration was studied. In this experiment, four identical sets of microcavity sensors were prepared. Each set of the microcavities had six samples that were immobilized with various amounts of Tir-IBD by exposing the sensor to different concentrations of Tir-IBD as described above. Purified Intimin-ECD solutions with different concentrations (5 μM to 60 μM) were then applied to each set of the sensors. The optical red shift of the microcavities was related to both the amount of Tir-IBD (linearly related to the red shift shown in FIG. 37) and Intimin-ECD, as shown in FIG. 38.

In general, the red shift of the sensors increased as the concentration of Intimin-ECD increased, which is consistent with the Tir-IBD immobilization assay. For a given concentration of Intimin-ECD, the red shift increased as the amount of immobilized Tir-IBD increased, which indicates that a larger amount of Intimin-ECD was captured by the sensor that had more Tir-IBD immobilized on its surface. As discussed in Example 15, the optimum probe concentration for biotin/streptavidin binding is ˜50%, which is attributed to the “pocket-type” binding site structure of the molecules (Ouyang et al., “Macroporous Silicon Microcavities for Macromolecule Detection,” Adv. Funct. Mater. 15(11): 1851-1859 (2005), which is hereby incorporated by reference in its entirety). For Tir-IBD/Intimin-ECD, the binding pocket is end-on and hence steric crowding at high Tir concentration does not appear to impact binding, as the magnitude of the Intimin shift is proportional to the Tir surface concentration. It can be seen from FIG. 38 that when the Intimin-ECD concentration was higher than 30 μM, non-specific binding of Intimin-ECD became detectable for the sensor without Tir-IBD. However, these results suggest that the sensor internal surface should be saturated with the probe molecule Tir-IBD to increase the ability of capturing Intimin-ECD. In that case, there are very few remaining aldehydes left, which can be efficiently deactivated by glycine methyl ester. Thus, all the sensors described below were treated with 50 μl of 1 mM Tir-IBD, which led to a saturated Tir-IBD surface coverage in the sensor.

FIG. 39 shows a calibration curve of the red shift of the sensor as a function of the target concentration. One can estimate the concentration of the Intimin-ECD solution based on the red shift of the spectra after the optical response of the microcavity is quantitatively characterized. The concentration sensitivity limit of the sensor is currently 4 μM of Intimin-ECD. The mass sensitivity of the sensor is estimated to be ˜20 pico mole/sensor by assuming that 10% of the protein in 50 μl solution that applied to the sensor was captured by the PSi matrix. Since the illumination spot size of the measurement was approximately 1 mm², the amount of Intimin-ECD that contributed to the red shift was approximately 130 femtomoles. The total internal surface area of the sensor is ˜15000 mm²; thus, the areal mass sensitivity is ˜50 pg/mm², which is consistent with the theoretical estimation.

To further demonstrate the selectivity of the sensor, a sensor array with two samples containing Tir-IBD and two samples without Tir-IBD were prepared. Protein supernatants obtained from the cell lystate of the INT-strain (BL21) and from strain JM109 (which does not express Intimin-ECD) were separately exposed to the Tir-IBD-functionalized sensors and the non-Tir-IBD functionalized sensors. Thus, a positive response should have been obtained only when the sensor with Tir-IBD immobilized on the macroporous silicon surface was exposed to the protein mixture containing Intimin-ECD (i.e. INT-strain cell lysate).

As shown in FIG. 39, a 5-nm red shift was obtained from the Tir-IBD functionalized sensor that was exposed to the protein mixture containing Intimin-ECD. A very small shift (<1 nm) was detected from the Tir-IBD functionalized sensor that was exposed to the protein mixture that did not contain Intimin-ECD. The sensors without Tir-IBD functionalization did not respond to either protein mixture (i.e., with or without Intimin-ECD). These results indicate that the sensor can be used to selectively detect Intimin-ECD from a protein mixture. Based on the red shift, the Intimin-ECD concentration in the protein mixture can be estimated using the calibration curve shown in FIG. 39. A 5-nm red shift corresponds to a 15 μM concentration of Intimin-ECD. To verify the Intimin-ECD concentration in the protein mixture, 2-D gel electrophoresis was used to compare the molecular weight bands of the mixture and the purified Intimin-ECD with known concentrations. Using the gel analysis function in Image J, the concentration of Intimin-ECD in the supernatants was estimated to be approximately 17 μM, which is very close to the estimation based on the optical response of the sensor.

The application of a macroporous silicon 1-D PBG microcavity as a quantitative analytical device for optical label-free biosensing application has been demonstrated. Moreover, target in a protein solution of which the target is a minority component (23%) of the total protein has been selectively and quantitatively detected.

### Example 18

### Advantages of PBG Microcavity Structures

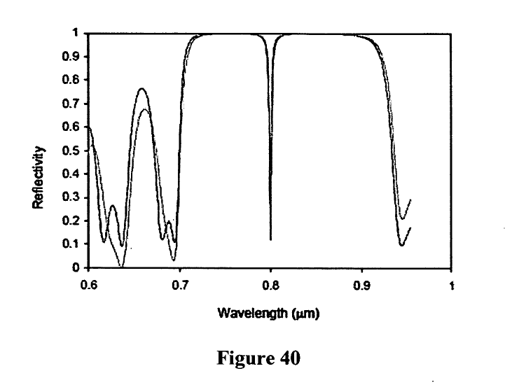

Because the analyte is present where the optical field intensity is large, (i.e., there is a large overlap between the field inside the microcavity and the analyte), PBG microcavity sensors have an advantage over sensing platforms that rely on the interaction between a small evanescent tail of the field and the analyte. For example, in microring cavities, Δλ/Δn is only 33 nm (Scheuer et al., “InGaAsP Annular Bragg Lasers: Theory, Applications, and Modal Properties,” IEEE J. Sel. Top. Quant. Electron. 11(2):476-484 (2005), which is hereby incorporated by reference in its entirety). PSi-based PBG sensors also have the advantage of size selectivity due to the tunable pore diameter. When the PSi sensor is exposed to a complex biological mixture, only the molecules that are smaller than the pores can be infiltrated into the sensor. Furthermore, as shown in FIG. 40, changing the refractive index on the top of the microcavity only causes changes to the side lobes in the reflectivity spectrum, not to the resonance dip. Thus, PSi PBG microcavities are more reliable than planar sensing platforms, where the capture of large size objects present in a “dirty” environment, for example by non-specific binding, may produce a false positive.

Although preferred embodiments have been depicted and described in detail herein, it will be apparent to those skilled in the relevant art that various modifications, additions, substitutions, and the like can be made without departing from the spirit of the invention and these are therefore considered to be within the scope of the invention as defined in the claims which follow.

What is claimed:

1. A macroporous microcavity structure comprising:
a porous semiconductor structure comprising a central microcavity interposed between upper and lower layers, each of the upper and lower layers comprising strata of alternating higher and lower relative porosity,
wherein the central microcavity comprises pores with an average pore size between about 50 nm and about 10 μm, and an average pore-to-pore distance of about 100 nm to about 30 μm.

2. The macroporous microcavity structure according to claim 1, wherein the pores are substantially straight.

3. The macroporous microcavity structure according to claim 1, wherein the pores are substantially smooth.

4. The macroporous microcavity structure according to claim 1, wherein the central microcavity has a porosity that is within a range defined by the porosity of the higher porosity strata of the upper and lower layers, ±5%.

5. The macroporous microcavity structure according to claim 1, wherein each of the upper and lower layers comprise four or more strata of alternating porosity.

6. The macroporous microcavity structure according to claim 1, wherein the strata of alternating porosity comprise first stratum having a porosity of about 30 to about 80 percent and second stratum having a porosity greater than the porosity of the first stratum.

7. The macroporous microcavity structure according to claim 1, wherein the porosity ratio of the higher porosity stratum:lower porosity stratum is between about 3.0 to about 1.05.

8. The macroporous microcavity according to claim 1, wherein the central microcavity comprise pores with an average pore size of about 50 to about 300 nm.

9. The macroporous microcavity according to claim 1, wherein the central microcavity comprise pores with an average pore-to-pore distance of about 100 nm to about 300 nm.

10. The macroporous microcavity according to claim 1, wherein the semiconductor structure comprises a material selected from the group of p-doped silicon, n-doped silicon, intrinsic or undoped silicon, silicon alloys, materials based on Group III element nitrides, and combinations thereof.

11. The macroporous microcavity according to claim 1, wherein the microcavity has a sensitivity (Δλ/Δn) of at least about 500 nm.

12. The macroporous microcavity according to claim 1, wherein the semiconductor structure has a resistivity of about 0.001 ohm-cm to about 20 ohm-cm.

13. A method of preparing a macroporous microcavity structure comprising:
providing a crystalline semiconductor wafer,
etching the wafer in a hydrofluoric acid based solution, with periodic changes in current density of between about 10 to about 40 mA/cm², under conditions effective to produce a macroporous microcavity structure of claim 1.

14. The method according to claim 13, wherein etching the wafer comprises one or more first etching steps performed under conditions effective to produce the upper layer.

15. The method according to claim 14, wherein the one or more first etching steps comprise a plurality of alternating etching periods (a) and (b), wherein (a) is effective to produce higher porosity stratum and (b) is effective to produce lower porosity stratum.

16. The method according to claim 13, wherein etching the wafer comprises one or more second etching steps performed under conditions effective to produce the central microcavity layer.

17. The method according to claim 16, wherein central layer is produced using conditions to achieve a porosity that is similar to the porosity of the higher porosity stratum of the upper or lower layers ±5%.

18. The method according to claim 13, wherein etching the wafer comprises one or more third etching steps performed under conditions effective to produce the lower layer.

19. The method according to claim 18, wherein the one or more third etching steps comprise a plurality of alternating etching periods (a) and (b), wherein (a) is effective to produce higher porosity stratum and (b) is effective to produce lower porosity stratum.

20. The method according to claim 13, further comprising, prior to said etching the wafer:
etching a sacrificial layer of the crystalline semiconductor wafer; and
electropolishing the crystalline semiconductor wafer to substantially remove the sacrificial layer and form a surface on the crystalline semiconductor wafer having a plurality of defects.

21. The method according to claim 20, wherein said etching the sacrificial layer comprises one or more etching periods of about 2 to about 30 seconds at a current density of about 10 to about 40 mA/cm².

22. The method according to claim 20, wherein said electropolishing comprises one or more etching periods of about 1 to about 2 seconds at a current density of about 200 to about 300 mA/cm².

23. The method according to claim 13, further comprising one or more etching stops between current pulses.

24. A biological sensor comprising:
a macroporous microcavity structure according to claim 1; and
one or more probes coupled to the macroporous microcavity structure and characterized by an ability to bind to a target molecule, whereby a detectable change occurs in a refractive index of the biological sensor upon binding of the one or more probes to the target molecule.

25. The biological sensor according to claim 24, wherein the central microcavity comprises substantially straight pores.

26. The biological sensor according to claim 24, wherein the central microcavity comprises substantially smooth pores.

27. The biological sensor according to claim 24, wherein the central microcavity comprise pores with an average pore size of about 50 to about 300 nm.

28. The biological sensor according to claim 24, wherein the central microcavity comprise pores with an average pore-to-pore distance of about 100 nm to about 300 nm.

29. The biological sensor according to claim 24, wherein the probe is selected from the group of non-polymeric small molecules, polypeptides or proteins, and oligonucleotides.

30. The biological sensor according to claim 24, further comprising:
one or more coupling agents each comprising a first moiety attached to the porous semiconductor structure and a second moiety which binds to the probe.

31. The biological sensor according to claim 30, wherein the one or more coupling agents are silanes.

32. The biological sensor according to claim 30 wherein each of the one or more probes comprises a plurality of binding sites, at least one of which binds to the target and at least one of which is bonded to the second moiety of the coupling agent.

33. The biological sensor according to claim 32 wherein the plurality of binding sites on the probe are the same, the biological sensor further comprising:
a plurality of blocking agents, each bonded to the second moiety of a coupling agent.

34. The biological sensor according to claim 33 wherein the plurality of blocking agents are amino acid alkyl esters.

35. The biological sensor according to claim 24 wherein the one or more probes are the same.

36. The biological sensor according to claim 24 wherein the one or more probes are coupled to the macroporous microcavity structure throughout the central layer and the upper and lower layers.

37. The biological sensor according to claim 24 wherein the one or more probes comprises two or more probes which are different, each binding to different target molecules.

38. The biological sensor according to claim 37 wherein the macroporous microcavity structure includes at least two zones, one of the two or more probes being bonded to the macroporous microcavity structure within a first zone and another of the two or more probes being bonded to the macroporous microcavity structure within a second zone.

39. A method of making a biological sensor which detects a target molecule, the method comprising:
providing a primed macroporous microcavity structure, wherein the primed macroporous microcavity structure comprises a macroporous microcavity structure according to claim 1 that has been primed for coupling with a probe; and
exposing the primed macroporous microcavity structure to a probe molecule including (i) one or more structure-binding groups and (ii) one or more target-binding groups that bind to a target molecule, said exposing being carried out under conditions effective to bind the probe molecule to the primed macroporous microcavity structure via a coupling agent or directly to the macroporous microcavity structure upon displacement of the coupling agent, with the one or more target-binding groups remaining available for binding to the target molecule.

40. A detection device comprising:
a biological sensor according to claim 24;
a source of illumination positioned to illuminate the biological sensor; and
a detector positioned to capture light reflected from the biological sensor and to detect changes in a reflectance spectrum of the biological sensor.

41. A method of detecting a target molecule comprising:
exposing a biological sensor according to claim 24 to a sample under conditions effective to allow binding of a target molecule in the sample to the one or more probes of the biological sensor; and
determining whether the biological sensor emits a reflectance spectrum which shifts following said exposing, whereby a shifted reflectance spectrum indicates the presence of the target molecule in the sample.

42. The method according to claim 41 wherein said determining comprises:
measuring a first reflectance spectrum prior to said exposing;
measuring a second reflectance spectrum after said exposing; and
comparing the first and reflectance spectra for a shift.

43. The method according to claim 41 wherein said measuring is carried out using a light source and a spectral analyzer.

44. The method according to claim 41 wherein the target molecule is a protein, glycoprotein, peptidoglycan, carbohydrate, lipoprotein, lipoteichoic acid, lipid A, phosphate, nucleic acid, or organic compound.

45. The method according to claim 41, further comprising quantifying the amount of target molecules present in the sample.

46. A method of detecting pathogenic Escherichia coli in a sample comprising:
performing the method according to claim 41 using a biological sensor comprising a probe that binds to Intimin,
wherein a change in the reflectance spectrum upon said determining indicates the presence of pathogenic E. coli in the sample.
